(19) United States
(12) Patent Application Publication
(10) Pub. No.: US 2024/0303278 A1
(43) Pub. Date: Sep. 12, 2024

(54) COMPUTER-IMPLEMENTED METHODS AND SYSTEMS FOR STRENGTHENING VIOLATED INEQUALITIES

(71) Applicant: David Michael WARME, Annandale, VA (US)

(72) Inventor: David Michael WARME, Annandale, VA (US)

(21) Appl. No.: 18/578,463

(22) PCT Filed: Jul. 22, 2022
(86) PCT No.: PCT/US22/38039

§ 371 Date: Jan. 11, 2024

Related U.S. Application Data
(60) Provisional application No. 63/225,111, filed on Jul. 23, 2021.
(60) Provisional application No. 63/245,326, filed on Sep. 17, 2021.

(51) Int. Cl. G06F 16/901

(52) U.S. Cl. CPC G06F 16/9027; G06F 16/9024

(57) ABSTRACT

Computer-implemented methods, systems and computer-readable storage medium for graphical tree generation between terminal points are provided which include augmenting one or more subtours. A method includes steps of receiving a terminal data set and generating an initial set of trees based on the terminal data set. Other steps include concatenating the initial set of trees to obtain a culled subset of trees that meet or exceed concatenation criteria, and outputting the culled subset of trees as a graph spanning the terminal points in the terminal data set. The concatenating includes augmenting one or more subtours by adding one or more vertices to strengthen violated inequalities. In one system a graph engine is configured to generate a graph spanning terminal points in the terminal data set based on an augmentation that adds one or more vertices to strengthen one or more violated subtour inequalities (S).

### TECHNICAL FIELD

The technical field relates to computer-implemented graph generation, design and modeling.

### BACKGROUND

Graphs are used in computer science and engineering in a variety of applications and industries. Graphs are data structures that can be used to represent connections or relationships between data. Graphs can be made up of a set of vertices and edges. Graphs can include one or more trees. Trees can have a hierarchy of levels with routes or paths extending from a root node along branches to a number of leaf nodes. See, e.g., S. Skiena, The Algorithm Design Manual. 3^{rd}. Ed., Springer-Verlag (2020), pp. 17-19 and 197-203.

Computer-aided design and modeling tools use and traverse graphs to model and analyze data and relationships between data. Graphs can be also be generated from input data or conditions relating to a model and traversed to solve problems and provide output helpful to users and engineers of a modeling tool. For example, graphs having trees are generated to identify relationships between terminal points. The terminal points can be in data used in modeling different physical components in semiconductor chip layouts, infrastructure networks (such as, energy or telecommunication network), or other models.

One type of tree used in graphs is a Steiner tree. A Steiner tree is a shortest network that spans a set of terminal points under a given metric. Additional points, called Steiner points, can be introduced to obtain a shorter spanning network between terminal points. In this way, a Steiner minimum tree (SMT) is generated. A SMT can be made up of unions of full Steiner trees (FSTs).

A two-phase approach to generate a SMT uses FST generation followed by FST concatenation to obtain a SMT between terminal points. A 1998 dissertation by one of the inventors further advanced the two-phase approach by (a) identifying FST concatenation as an instance of a minimum spanning tree (MST) in hypergraph problem, (b) formulating a MST in hypergraph as an integer problem (IP), and (c) solving the IP with a branch and cut technique. See, D. Juhl et al., “The GeoSteiner Software Package for Computing Steiner Trees in the Plane: An Updated Computational Study,” Math Programming Computation, 10:487-532, Springer, 2018; and D. Warme, Spanning Trees in Hypergraphs with Applications to Steiner Trees, PHD thesis, University of Virginia, 1998. One use of the two-phase approach has been implemented in a GeoSteiner software package, version 5.1, available from GeoSteiner, Inc. Copyright 1998, 2015 http://www.geosteiner.com/.

One conventional implementation of the GeoSteiner package uses the two-phase approach to solve a geometric Steiner tree problem, that is, is to find a SMT for a set of terminal points. To illustrate, consider the examples of FIGS. 6-8. FIG. 6 illustrates an example terminal point set made up of a finite set T of 100 terminal points. Given the set T, to solve the geometric Steiner problem, the goal is to find a set of line segments of minimum length that connect all the terminal points in set T. First, a metric must be specified for measuring distance. A distance (d) between two points s,t is commonly expressed as

$$d = {( {\vert {x}_{1} - {x}_{2} \vert}^{p} + {\vert {y}_{1} - {y}_{2} \vert}^{p} )}^{1 / p}$$

where the location of point s is denoted by the coordinates (x₁, y₁) and the location of point t is denoted by the coordinates (x₂, y₂), and p≥1 is a constant defining a particular metric. Two metrics are often used. These metrics are referred to a Euclidean metric (L₂), where p=2; and a rectilinear metric (L₁), where p=1.

FIG. 7 is a diagram illustrating an example Euclidean solution having a Steiner minimum tree 700 connecting the terminal point set of FIG. 6. In one example run on a conventional GeoSteiner package version 5.1, Euclidean SMT 700 was generated having a length equal to about 6.665750289411368 in about 0.50 seconds.

FIG. 8 is a diagram illustrating an example rectilinear solution having a SMT 800 connecting the terminal point set of FIG. 6. In one example run on a conventional GeoSteiner package version 5.1, rectilinear SMT 800 was generated having a length equal to 7.5270366 in about 0.03 seconds.

Conventional approaches to generating a SMT between terminal points however have been computationally difficult in reasonable time periods and limited to a small number of terminal points. As reported by Juhl et al., for a rectilinear SMT problem, one prior effort by A. B. Kahng et al. was limited to 16 points. See, Juhl et al. at p. 2 and A. B. Kahng et al., Highly scalable algorithms for rectilinear and octilinear Steiner trees, Proceedings of the Asia and South Pacific Design Automation Conference, pages 827, 833, New York, 2000. As reported by Juhl et al., for a Euclidean SMT problem, one prior effort by P. Winter et al. was limited to 28 points. See, Juhl et al. at p. 2 and P. Winter and M. Zachariasen, Euclidean Steiner minimum trees: An improved exact algorithm, Networks, 30:149-166, 1997. The PHD thesis of D. Warme (one of the co-inventors) further reported a computation result of 1000 points for rectilinear and 2000 points for Euclidean as reported by Juhl et al. See, Juhl et al. at p. 2 and 1998 D. Warme PHD thesis.

### SUMMARY

The present disclosure relates to computer-implemented graph generation.

In an embodiment, a computer-implemented method for graphical tree generation between terminal points is provided which includes augmenting one or more subtours. The method includes steps of receiving a terminal data set and generates an initial set of trees based on the terminal data set. Each tree couples two or more terminal points in the terminal data set. The method further includes the steps of concatenating the initial set of trees to obtain a culled subset of trees that meet or exceed concatenation criteria, and outputting the culled subset of trees as a graph spanning the terminal points in the terminal data set. The concatenating includes augmenting one or more subtours by adding one or more vertices to strengthen violated inequalities.

In another embodiment, a computer-implemented system for graphical tree generation includes a storage device configured to store a terminal data set and a graph engine, implemented on at least one processor. The graph engine is configured to generate a graph spanning terminal points in the terminal data set based on an augmentation that adds one or more vertices to strengthen violated inequalities of one or more subtours (S).

A number of further features may be provided in further embodiments. The initial set of trees may include full Steiner trees (S). The graph output may be a Steiner minimum tree between the terminal points. The strengthened violated inequalities may be comprised of one or more methods that augment violated subtour inequalities by adding one or more vertices as described herein.

Still further features in embodiments may be augmenting that includes adding vertices to a subtour in a hypergraph formed from the initial subset of trees, performing a single vertex augmentation to a subtour, performing a greedy augmentation of subtour inequalities by repeatedly performing single vertex augmentation to a subtour, adding complementary connected components to a subtour, and/or adding complementary biconnected components to a subtour.

In a further embodiment, a graph engine includes a graph generator and a graph concatenator. The graph generator is configured to generate an initial set of full Steiner trees (FSTs) based on the terminal data set, wherein each FST couples two or more terminal points in the terminal data set. The graph concatenator has an augmenter and is configured to concatenate the initial set of FSTs to obtain a culled subset of FSTs that meet or exceed concatenation criteria and to output the culled subset of FSTs. The augmenter is configured to perform an augmentation of one or more vertices that strengthen a violated subtour inequality evaluated during the FST concatenation.

In another embodiment, a computer-implemented system for graphical tree generation between terminal points has means for storing a terminal data set and means for adding one or more vertices to strengthen inequality violations of one or more subtours (S) and obtain a graph spanning terminal points in the terminal data set.

In another embodiment, a computer-readable storage medium having control logic for causing at least one processor to generate a graph between terminal points includes first and second control logic. The first control logic is configured to enable retrieval of a terminal data set. The second control logic is configured to enable adding one or more vertices to strengthen one or more violated subtour inequalities (S) and obtain a graph spanning terminal points in the retrieved terminal data set.

Further embodiments, features, and advantages of the invention, as well as the structure and operation of the various embodiments of the invention are described in detail below with reference to accompanying drawings.

### BRIEF DESCRIPTION OF THE DRAWINGS

Embodiments are described with reference to the accompanying drawings. In the drawings, like reference numbers may indicate identical or functionally similar elements. The drawing in which an element first appears is generally indicated by the left-most digit in the corresponding reference number.

FIG. 1A illustrates a block diagram of an electronic design system in accordance with one or more embodiments described herein. FIG. 1B illustrates a block diagram of another electronic design system in accordance with one or more embodiments described herein.

FIG. 2 is a flowchart diagram of a method for graphical tree generation according to an embodiment.

FIG. 3 is a flowchart diagram showing in further detail the initialization of hypergraph H of FIG. 2 according to an embodiment.

FIG. 4 is a flowchart diagram showing in further detail iterative satisfaction of all subtours in the concatenation step of FIG. 2 according to an embodiment.

FIG. 5A is a diagram showing different routines for augmenting subtours to strengthen a violated inequality according to embodiments. FIG. 5B is a diagram illustrating that removing a 5-vertex edge from a tree yields 5 connected components. FIG. 5C is a diagram illustrating a tree for which the subhypergraph induced by subset S of the vertices is in general a forest of trees (2 in this example).

FIG. 6 is a diagram illustrating an example terminal point set.

FIG. 7 is a diagram illustrating an example Euclidean solution having a Steiner minimum tree (SMT) connecting the terminal point set of FIG. 6.

FIG. 8 is a diagram illustrating an example rectilinear solution having a SMT connecting the terminal point set of FIG. 6.

FIG. 9 is a diagram illustrating an example Euclidean Steiner tree computation during FST concatenation according to an embodiment.

FIG. 10 is a diagram illustrating an example rectilinear Steiner tree computation during FST concatenation according to an embodiment.

FIG. 11A is a diagram illustrating a violated subtour S with multiple holes in augmentation of connected components according to an embodiment.

FIG. 11B is a diagram illustrating a larger violated subtour S3 compared to a relatively smaller violated subtour S (of FIG. 11A) according to an embodiment.

FIGS. 12A and 12B are line diagrams illustrating larger subtours have greater strength than smaller size subtours for the respective extreme point ratio (EPR) and centroid distance (CD) metrics.

FIG. 13 is a flowchart diagram illustrating a reduction during concatenation using single vertex deletion, connected and bi-connected components according to an embodiment.

FIG. 14 is a flowchart diagram illustrating a process for strengthening violated inequalities by using reduction with greedy deletion of vertices according to an embodiment or by using augmentation with greedy addition of vertices according to an embodiment.

FIG. 15 shows an example Sparse Orthogonal Stratified (SOS) heuristic algorithm according to an embodiment.

FIG. 16 shows an example greedy augmentation algorithm according to an embodiment.

FIG. 17 shows an example heap algorithm according to an embodiment.

FIG. 18 shows an example illustration of augmentation via complementary biconnected components having a violated hole inequality according to an embodiment.

FIG. 19 shows an example pseudo cost recalculation heuristic algorithm according to an embodiment.

FIG. 20 shows an example illustration of a small subtour S together with a small hole H according to an embodiment.

FIGS. 21A, 21B, 21C, 21D, 21E and 21F show tabulated results for example graphs processed with augmentation that adds one or more vertices to strengthen one or more violated subtour inequalities (S) according to embodiments.

### DETAILED DESCRIPTION

The present disclosure describes improved computer-implemented graph generation and electronic design and modeling. Computer-implemented methods, systems, computer program products and devices for graphical tree generation between terminal points which include augmenting one or more subtours are described in embodiments. Electronic design and modeling tools using graph generation and tree traversal, and applications thereof in semiconductor layout design, infrastructure design, quantum computing, microfluidics, or other modeling are described.

Embodiments refer to illustrations described herein with reference to particular applications. It should be understood that the invention is not limited to the embodiments. Those skilled in the art with access to the teachings provided herein will recognize additional modifications, applications, and embodiments within the scope thereof and additional fields in which the embodiments would be of significant utility.

In the detailed description of embodiments herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The following detailed description is merely illustrative and not intended to limit the scope and/or use of embodiments. Furthermore, there is no intention to be bound by any expressed or implied information presented in the preceding Background or Summary sections, or in the following Detailed Description section.

One or more embodiments are now described with reference to the Drawings, where like referenced numerals are used to refer to like elements throughout. In the following Detailed Description, for purposes of explanation, numerous specific details are set forth in order to provide a more thorough understanding of the one or more embodiments. However, it is evident that one or more embodiments can be practiced without these specific details.

### Terminology

A term “graph” as used herein refers to a computer-readable data structure that represents connections or relationships between data. A graph can be made up of a set of vertices and edges. Edges can have numeric weights (which can be positive, zero, or negative in various applications). Terminals are a subset of vertices of a graph. A graph can be made up of one or more trees. The edge weights can model distance (measured according to some distance metric). The terms “weight” and “length” (or “total weight” and “total length”) are used interchangeably herein.

A “tree” as used herein is a computer-readable data structure having one or more vertices (also called nodes) connected by branches that extend between nodes. A tree may include a root node having one or more branches that extend to other nodes in one more levels of the tree. Leaf nodes are nodes at the furthest ends of branches from root nodes. Trees are connected (there is a path between every pair of nodes) and have no cycles (this path is unique).

A Steiner tree as used herein is a tree that couples a subset of vertices (or terminals) of a graph having weighted edges. A Steiner tree may include added vertices also called Steiner points or Steiner vertices which are not part of the original terminals. A Steiner tree may include but not is not limited to a Euclidean Steiner tree, rectilinear tree, or other type of Steiner tree as would be apparent to a person skilled in the art given this description.

A full Steiner tree (or FST) as used herein refers to a tree having a minimum length which couples a subset of two or more terminals of an edge-weighted graph. In one example, a full Steiner tree may be a locally-optimal tree (for example, having a minimum length) and connecting a subset of two or more terminals of an edge-weighted graph such that all terminals are leaf nodes of the FST. In further examples, a tree has a full topology if all of the terminal vertices have degree 1 (i.e., are “leaves” of the tree). A subset F of the terminals T is called a full set if every Steiner minimum tree of F has full topology. A tree in these examples then is a full Steiner tree if it is a Steiner minimum tree over a full set F of terminals.

FST Generation as used herein refers to a process by which a set of FSTs is constructed (according to a specified distance metric) for a given set of terminals. Generated FSTs must be sufficient which means they contain a subset of FSTs forming an optimal tree connecting all terminals. Such sufficiency is obtained by considering all possible FSTs and discarding only those that can be proven sub-optimal or redundant.

FST Pruning as used herein refers to a process by which the entire set of FSTs is examined, discarding those that cannot appear in an optimal tree (a Steiner minimum tree spanning the entire set of terminals), and marking as “required” those that must be present in every optimal tree.

FST Concatenation as used herein is a process of identifying a culled set of FSTs that forms an optimal tree for a given set of terminals.

The term subtour elimination constraints (also referred to simply as “subtours”) as used herein refers to a particular type of inequality whose effect is to prohibit cycles appearing within a specified subset S of vertices.

A polyhedron as used herein consists of the intersection of a finite number of linear equations and/or linear half-spaces in Euclidean space Rⁿ.

A polytope as used herein is a polyhedron that is finitely bounded.

An extreme point of polytope P as used herein is a point xϵP for which there is a hyperplane H such that H∩P={x}. (Extreme points are “corners” of the polytope.) Every polytope has a finite number of extreme points.

The extreme point ratio (EPR) of a given inequality ax≤b (or equivalently −ax≥−b) with respect to a polytope P as used herein is |I|/|X|, where X is the set of all extreme points of P, and I={xϵX:ax=b}.

The centroid distance (CD) of a given inequality ax≤b (or equivalently −ax≥−b) with respect to a polytope P as used herein is the shortest distance between centroid C and the hyperplane ax=b, where X is the set of all extreme points of P, and centroid Cis the mean of all members of X. (There are two versions: the weak centroid distance where distance is measured along a line that must reside entirely within the affine hull of P; and the centroid distance where distance is measured along a line that must reside entirely within P.)

### Electronic Design Systems

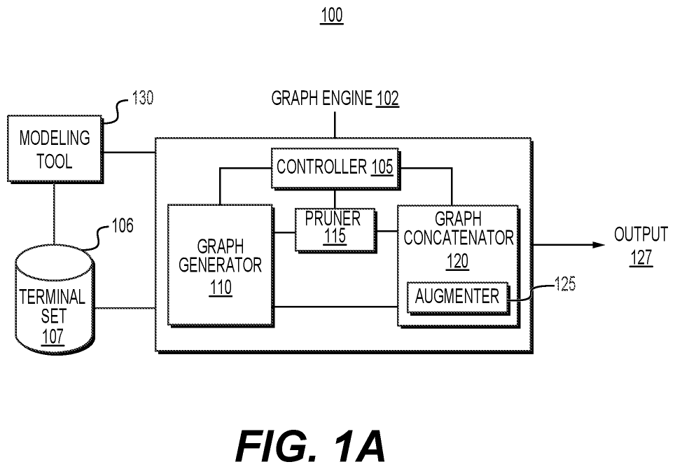

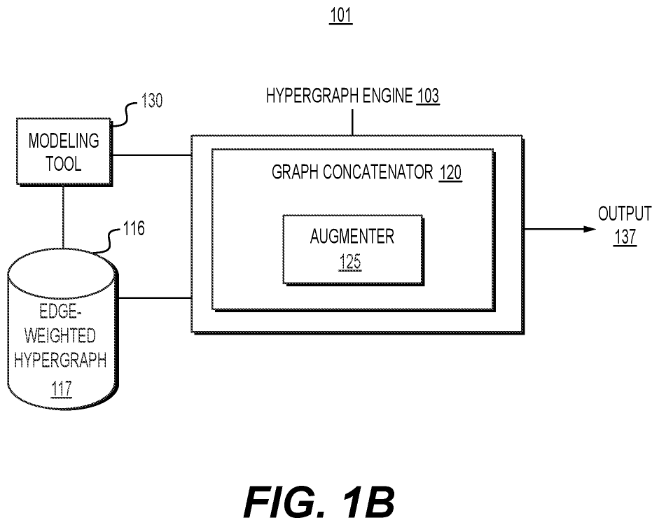

FIG. 1A illustrates a block diagram of an electronic design system 100 in accordance with one or more embodiments described herein. System 100 includes a graph engine 102 coupled to a storage device 106. Storage device 106 is configured to store a terminal data set 107. Terminal data set 107 may include a set of one or more terminal points. Graph engine 102 is configured to generate a graph spanning terminal points in terminal data set 107. The graph is generated based on an augmentation that adds one or more vertices to strengthen one or more violated subtour inequalities (S) as described further below. The generated graph 127 (also referred to as output 127) may be output for display, storage or transmission at the same or different physical location. For example, generated graph 127 may be stored in storage device 106 for access and retrieval by a modeling tool 130.

As shown in FIG. 1A, in an embodiment, graph engine 102 includes a controller 105, graph generator 110, pruner 115, and graph concatenator 120. Controller 105 may control the initiation of and sequence or timing of operation of any one or more of graph generator 110, pruner 115, or graph concatenator 120 in response to inputs to or outputs from graph engine 102. Graph generator 110 generates an initial set of trees based on terminal data set 107. Pruner 115 may prune the initial set of trees to remove redundant or undesirable trees. Pruner 115 is optional and may be omitted or bypassed for certain graphs and applications as desired. Graph concatenator 120 concatenates the initial set of trees from graph generator 110 (or the pruned set from pruner 115) to obtain a culled set of trees that meet or exceed concatenation criteria. The culled set of trees (also referred to as a graph) is then output by graph engine 102 as output 127. Concatenation criteria may include, for example, forming a tree that spans all terminals with no cycles, and has a minimum total length.

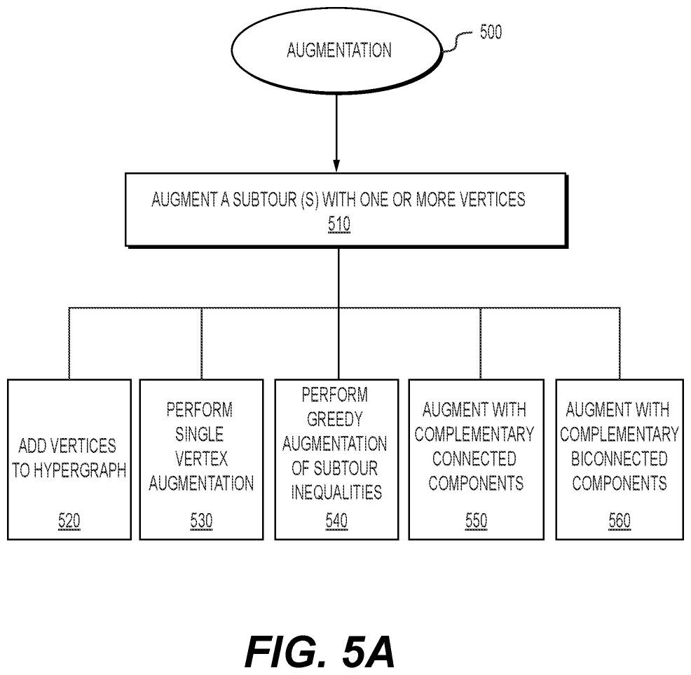

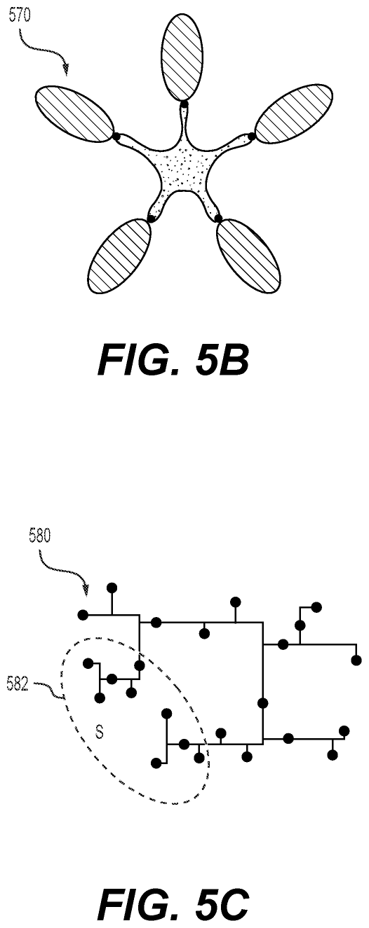

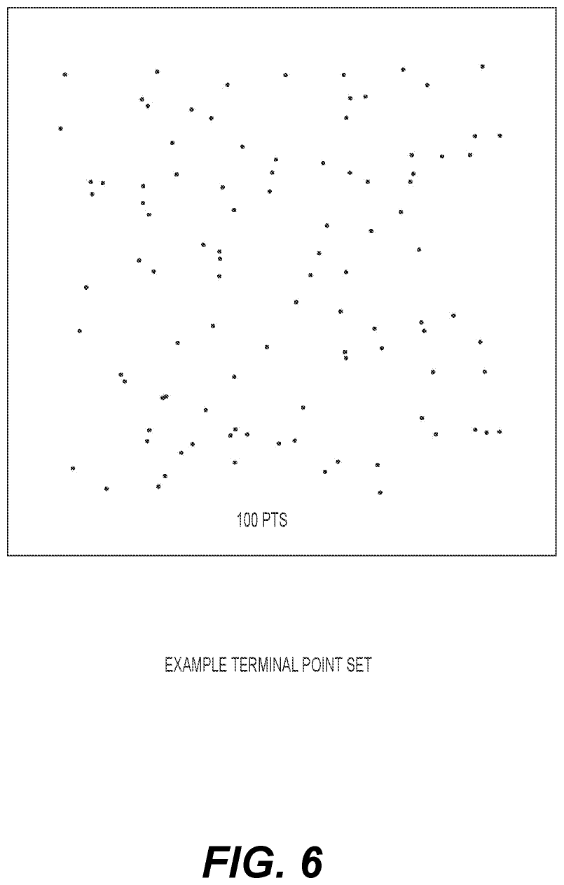

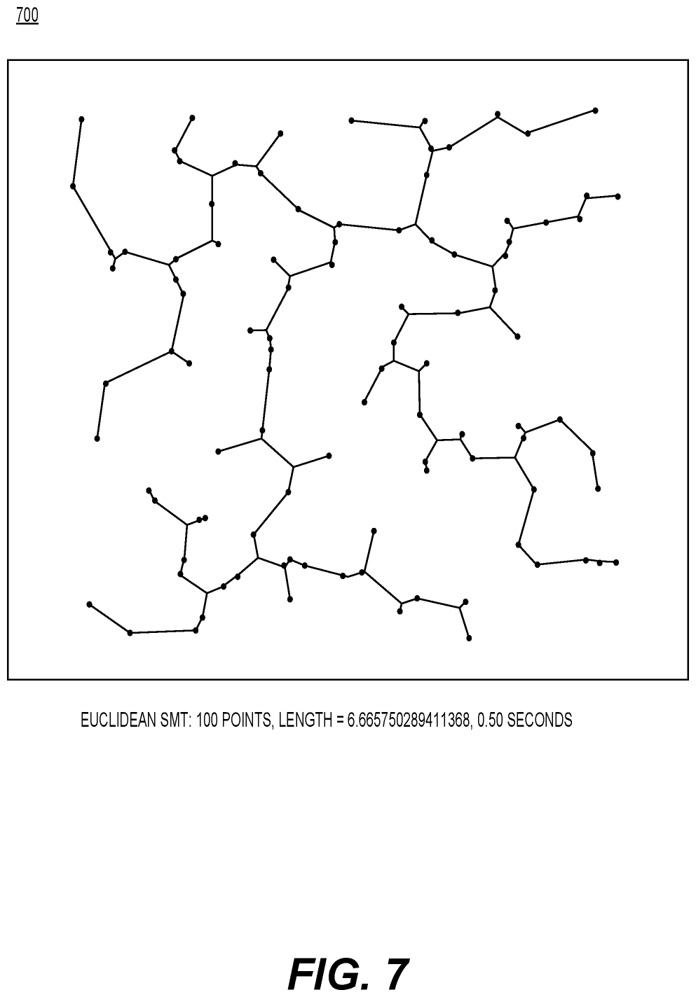

In a further feature, graph concatenator 120 includes an augmenter 125. Augmenter 125 performs an augmentation that adds one or more vertices to strengthen one or more violated subtours evaluated during the concatenation. In embodiments, augmenter 125 may perform different types of augmentation and combinations thereof as described further below with respect to FIG. 5A.

The trees generated by graph generator 110 and processed in graph engine 102 can be any type of tree structure or combination of trees including, but not limited to, full Steiner trees (FSTs) and/or hypergraphs. In one example, FSTs may be used where each FST couples two or more terminal points in the terminal data set.

Graph engine 102 can be used with trees having data and structures used in a variety of applications, such as, computer-aided design and modeling. Modeling tool 130 can be any type of modeling tool that models physical and virtual representations with model data. The model data for example can include a terminal data set. In this way, model tool 130 can model a physical representation with model data that includes the terminal data set, and can receive an output 127 (graph) generated by graph engine 102 that spans the terminal points in the terminal data.

A number of different types of models and graphs can be used in a variety of applications, such as, semiconductor fabrication design, infrastructure design, quantum computing and microfluidics. For example, graph 127 may be representative of semiconductor layouts and paths and routes therein used in semiconductor fabrication design. Modeling tool 130 may be a design tool that models a physical representation of a semiconductor chip layout. The terminal data set 107 then includes terminal points representative of physical locations within a plane of the semiconductor chip layout. In another example, modeling tool 130 may be a design tool that models a physical representation of an infrastructure layout (such as a gas or oil pipeline or telecommunication network), and the terminal data includes terminal points representative of physical locations within the infrastructure layout.

In some embodiments, modeling tool 130 may be a design tool that models a structural representation of such physical systems, including circuit schematic diagrams or net lists, or network topologies.

In one embodiment, graph 127 may be a tree (T) that spans all terminals in the terminal data set 107 with no cycles and has a minimum length. In a further embodiment, the graph 127 generated by graph engine 102 is a Steiner minimum tree (SMT) between the terminal points, such as, a minimum spanning tree of a hypergraph generated to couple the vertices of said hypergraph. In another embodiment, the generated graph 127 is made up of one or more full Steiner trees between the terminal points.

In some embodiments, output 127 may consist of data indicating that no tree spanning the given terminals exists. (This should not happen for a hypergraph generated from a set of FSTs that is sufficient.)

In one embodiment, graph engine 102 is further configured to generate an initial set of trees based on the terminal data set, and concatenate the initial set of trees to obtain a culled subset of trees that meet or exceed concatenation criteria. Each tree couples two or more terminal points in the terminal data set. Concatenation criteria may include, but is not limited to, generating graph 127 so that it spans all terminals in the terminal data set 107 with no cycles and has a minimum length.

Electronic design system 100 including graph engine 102 (and any of its components 105, 110, 115, 120, 125) or modeling tool 130 may be implemented in software, firmware, or hardware, or a combination thereof. In various embodiments, electronic design system 100 including graph engine 102 (and any of its components 105, 110, 115, 120, 125) or modeling tool 130 can be implemented on one or more computing devices. The computing devices may be at the same or different locations. A computing device can be any type of device having one or more processors and computer-readable memory. For example, a computing device can be a workstation, mobile device (e.g., a mobile phone, personal digital assistant, tablet or laptop), computer, server, computer cluster, server farm, cloud computing services platform, game console, set-top box, kiosk, embedded device or system, or other device having at least one processor and computer-readable memory. In addition to at least one processor and memory, such a computing device may include software, firmware, or hardware, or a combination thereof. Software may include one or more applications and/or an operating system. Hardware can include, but is not limited to, a processor, memory, or user interface, or other input/output device.

The operation of the electronic design system 100 including graph engine 102 is described in further detail below with reference to method 200.

FIG. 1B illustrates a block diagram of an electronic design system 101 in accordance with one or more embodiments described herein. System 101 includes a hypergraph engine 103 coupled to a storage device 116. Storage device 116 is configured to store an edge-weighted hypergraph data set 117. Edge-weighted hypergraph data set 117 may include a set V of zero or more vertices, a set E of zero or more edges (sometimes called trees), and may include a numeric weight for each edge. (The weights may be positive, zero or negative, as required by various applications.) Hypergraph engine 103 can be configured to receive or retrieve an edge-weighted hypergraph from storage device 116 in one embodiment, or from modeling tool 130 in other embodiments. After processing by hypergraph engine 103, a generated hypergraph 137 (also referred to as output 137) may be output for display, storage or transmission at the same or different physical location. For example, generated hypergraph 137 may be stored in storage device 116 for access and retrieval by a modeling tool 130.

In some embodiments, edge-weighted hypergraph 117 may contain additional data that partitions the set V of vertices into two subsets: the set T denoting terminal vertices, and the set N denoting Steiner vertices. Such embodiments may also specify numeric weights for each Steiner vertex. (The weights may be positive, zero or negative, as required by various applications.)

In some embodiments, output 137 may consist of data indicating that no tree spanning the given vertices V (or terminal vertices T) exists.

As shown in FIG. 1B, in an embodiment, hypergraph engine 103 includes a graph concatenator 120. Graph concatenator 120 concatenates the initial set E of hypergraph edges to obtain a culled set of edges that meet or exceed concatenation criteria. The culled set of edges (also referred to as a graph or hypergraph) is then output by hypergraph engine 103 as output 137. Concatenation criteria may include, for example, forming a tree that spans all vertices V with no cycles, and having minimum total edge weight. In embodiments where vertices are partitioned as terminals T and Steiner vertices N, concatenation criteria may include, for example, forming a tree that spans all terminals T with no cycles, and having minimum total weight of edges, Steiner vertices, or both.

In a further feature, graph concatenator 120 includes an augmenter 125. Augmenter 125 performs an augmentation that adds one or more vertices to strengthen one or more violated subtours evaluated during the concatenation. In embodiments, augmenter 125 may perform different types of augmentation and combinations thereof as described further below with respect to FIG. 5.

The edges (or trees) processed in hypergraph engine 103 can represent any type of tree structure or relationship between the application entities modeled as vertices V. In one example, edges may represent obstacle-avoiding rectilinear FSTs that couple two or more terminals or Steiner vertices in the edge-weighted hypergraph data set.

Hypergraph engine 103 can be used with edges/trees having data and structures used in a variety of applications, such as, computer-aided design and modeling. Modeling tool 130 can be any type of modeling tool that models physical and virtual representations with model data. The model data for example can include an edge-weighted hypergraph data set. In this way, modeling tool 130 can model a physical representation with model data that includes the edge-weighted hypergraph data set, and can receive an output 137 (hypergraph or culled set of edges) generated by hypergraph engine 103 that spans the vertices (or terminals) in the edge-weighted hypergraph data.

A number of different types of models and hypergraphs can be used in a variety of applications, such as, semiconductor fabrication design, infrastructure design, quantum computing and microfluidics. For example, hypergraph 137 may be representative of semiconductor layouts and paths and routes therein used in semiconductor fabrication design. Modeling tool 130 may be a design tool that models a physical representation of a semiconductor chip layout. The edge-weighted hypergraph data set 117 then includes vertices representative of physical locations within a plane of the semiconductor chip layout. In another example, modeling tool 130 may be a design tool that models a physical representation of an infrastructure layout (such as a gas or oil pipeline or telecommunication network), and the edge-weighted hypergraph data includes vertices representative of physical locations within the infrastructure layout.

In some embodiments, modeling tool 130 may be a design tool that models a structural representation of such physical systems, including circuit schematic diagrams or net lists, or network topologies.

In one embodiment, hypergraph 137 may be a tree that spans all vertices in the edge-weighted hypergraph data set 117 with no cycles and having minimum total edge weight. In a further embodiment, the hypergraph 137 generated by hypergraph engine 103 may be a Steiner minimum tree (SMT) between the terminal vertices T.

Electronic design system 101 including hypergraph engine 103 (and any of its components 120, 125) or modeling tool 130 may be implemented in software, firmware, or hardware, or a combination thereof. In various embodiments, electronic design system 101 including hypergraph engine 103 (and any of its components 120, 125) or modeling tool 130 can be implemented on one or more computing devices. The computing devices may be at the same or different locations. A computing device can be any type of device having one or more processors and computer-readable memory. For example, a computing device can be a workstation, mobile device (e.g., a mobile phone, personal digital assistant, tablet or laptop), computer, server, computer cluster, server farm, cloud computing services platform, game console, set-top box, kiosk, embedded device or system, or other device having at least one processor and computer-readable memory. In addition to at least one processor and memory, such a computing device may include software, firmware, or hardware, or a combination thereof. Software may include one or more applications and/or an operating system. Hardware can include, but is not limited to, a processor, memory, or user interface, or other input/output device.

The operation of the electronic design system 101 including hypergraph engine 103 is described in further detail below with reference to steps 240 and 250 of method 200.

### Graphical Tree Generation

FIG. 2 is a flowchart diagram of a computer-implemented method for graphical tree generation 200 according to an embodiment (steps 210-250). In one embodiment, method 200 may be carried out by graph engine 102. For example, graph engine 102 may include a controller 105 to initiate and control operation of steps 210-250. For brevity, method 200 is described with respect to system 100 and graphic engine 102, however this is not intended to be limiting and method 200 (including each of its steps) may be used with other systems or configurations as would be apparent to a person skilled in the art given this description.

First, a terminal data set is received (step 210). For example, graph engine 102 may receive terminal data 107 by accessing storage device 106 or by having it sent to graph engine 102 by modeling tool 130 or other tool or controller that initiates operation. Terminal data set 107 includes data identifying a number of terminal points.

In step 220, an initial set of trees F is generated based on terminal data set 107. For example, control may proceed to graph generator 110. Graph generator 110 generates an initial set of trees. Each tree couples two or more terminal points in terminal data set 107.

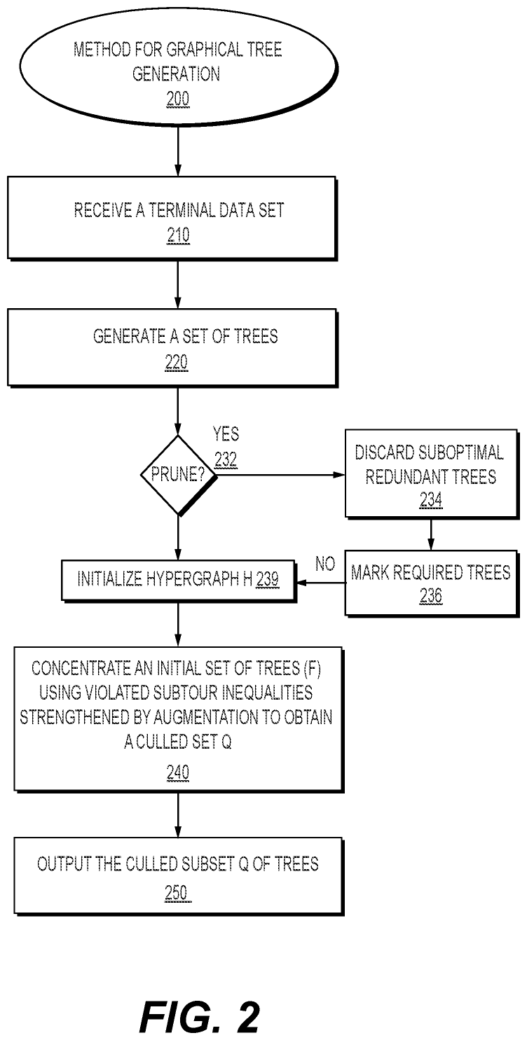

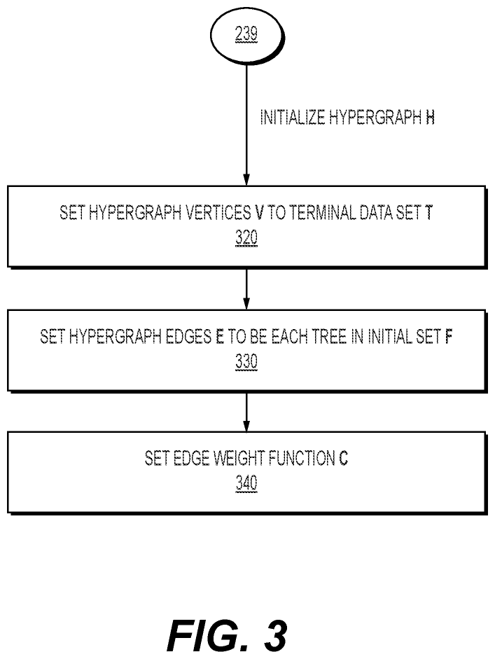

In step 232, graph engine 102 decides whether to prune the initial set of trees. If yes, prune, control proceeds to steps 234 and 236. In step 234, suboptimal or redundant trees are discarded (that is removed from the initial set). Remaining trees that must be present in every optimal culled set are marked “required” (step 236). In one example, pruner 115 may traverse the initial set of trees and identify redundant trees (which includes branches or parts of trees) that have redundant data or are suboptimal. In some embodiments, optimality is determined solely by the sum of the weights of edges culled for the final solution tree. Some embodiments might use edge weights that discourage selection of edges that are overly complex, have too many levels or more branches then are needed. Some embodiments might use non-linear objective functions, such as the Elmore metric. After step 236, control then proceeds to step 239. If no pruning is decided at step 232, then control proceeds to step 239. Pruner 115 is then not used. In step 239, the terminals and trees are used to initialize a weighted hypergraph, as described in FIG. 3.

Concatenation with Augmentation

In step 240, the initial set of trees F are concatenated using violated subtour inequalities strengthened by augmentation to obtain a culled subset of trees Q. For example, graph concatenator 120 concatenates the initial set of trees F (that is, those output by graph generator 110 or the pruned set output by pruner 115) to obtain a culled subset Q of trees that meet or exceed concatenation criteria. During concatenation, augmenter 125 augments one or more subtours (S) by adding one or more vertices to strengthen violated subtour inequality (S). Step 240 is described further below with respect to FIG. 5.

Consider further a method for strengthening certain constraints used in certain optimization problems.

Given:

An optimization solution xϵRⁿ

A linear inequality a x≤b (violated by x)

Find:

New linear inequality c x≤d (also violated by x) that is a stronger inequality (larger reduction of feasible space).

The method has three phases that may be applied or repeated in various sequences:

Iteratively adding one vertex (having certain properties) to the violated subset

Adding vertices to the violated set using complementary connected components.

Adding vertices to the violated set using complementary biconnected components.

In step 250, the culled subset Q is output. For example, the culled subset of trees Q may be an output 127 from graph engine 102 that represents a graph spanning the terminal points in the terminal data set 107. In an additional example, the culled subset of trees Q may be an output 137 from hypergraph engine 103 that represents a tree spanning the terminal vertices T in the edge-weighted hypergraph data set 117, including as many or few of the Steiner vertices N as necessary to meet or exceed concatenation criteria.

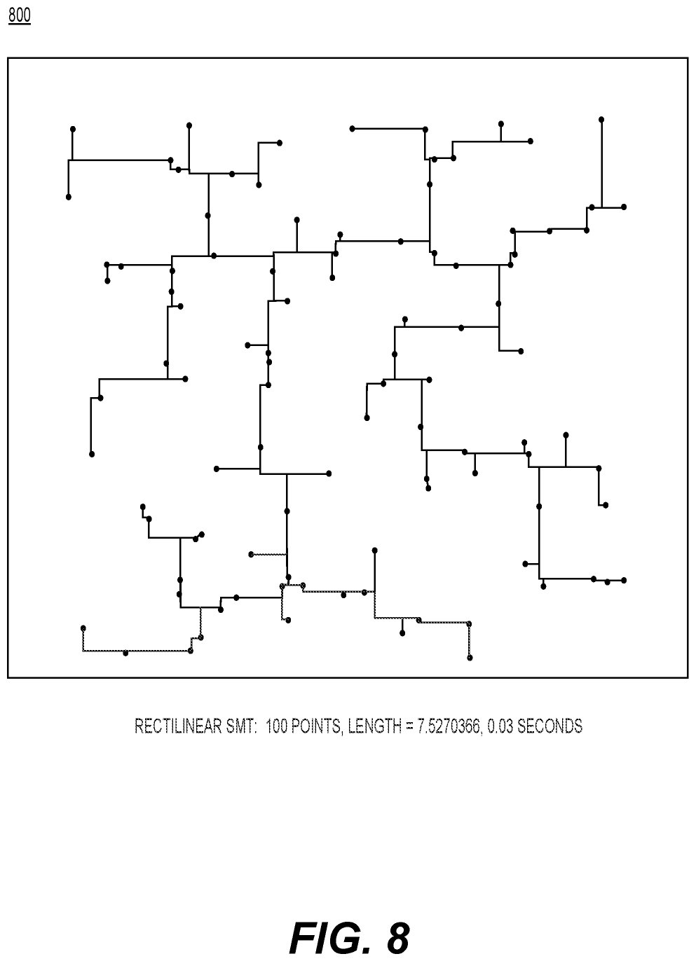

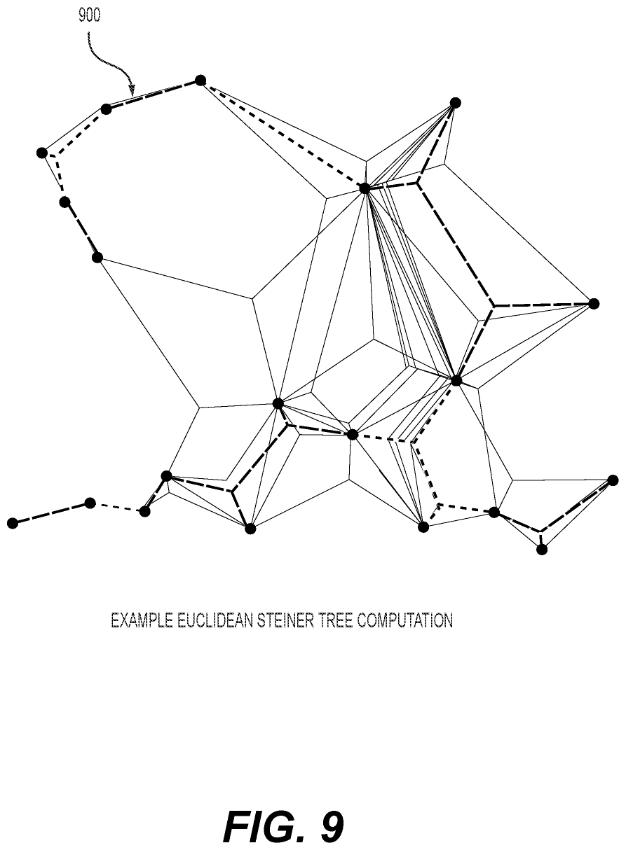

FIG. 9 illustrates a Euclidean Steiner minimum tree (SMT) 900 between input terminal points obtained by concatenating Euclidean FSTs. SMT 900 is comprised of the culled Euclidean FSTs (shown in small and large dash lines) that connect all the terminal points. Thinn grey lines are also provided to show initial FSTs that were omitted from the final culled set forming SMT 900.

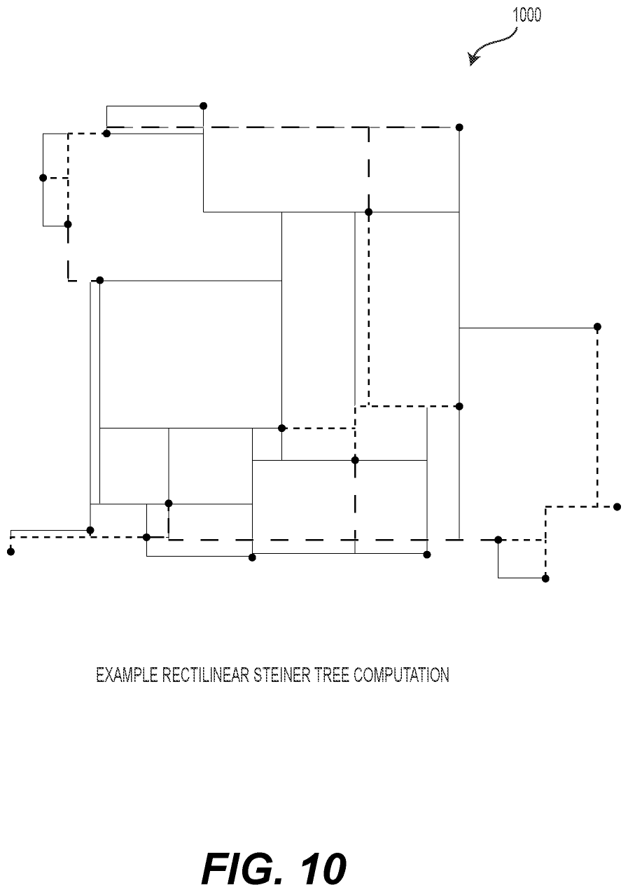

Similarly, FIG. 10 illustrates a rectilinear Steiner minimum tree (SMT) 1000 between input terminal points obtained by concatenating rectilinear FSTs. SMT 1000 is comprised of the culled rectilinear FSTs (shown in small and large dash lines) that connect all the terminal points. Thin grey lines are also added to show initial FSTs that were omitted from the final culled set forming SMT 1000.

As shown in FIG. 3, initialization step 239 may include further steps 320-340. In an embodiment, each of steps 320-340 is performed by graph concatenator 120. For brevity, FIG. 3 is described with reference to an example having an initial set F of full Steiner trees (FSTs). However, this example is not intended to be limiting. A set F may be made up of other types of trees or portions of trees.

In steps 320-340, a hypergraph H is initialized. The hypergraph H may be a hypergraph that includes all of the initial set of trees F remaining after step 220 or after pruning (steps 234 and 236). The hypergraph H may include all vertices and branches in the initial set of trees F.

In step 320, hypergraph vertices V are set to terminal points in terminal data set T.

In step 330, hypergraph edges E are set to be each tree in the initial set F.

As result of steps 320-330, given a terminal set T and set F of FSTs, the following output can be obtained:

Hypergraph H=(V, E), where V=T, and E=F, such that each FST becomes an edge over terminals and/or added vertices.

In step 340, an edge weight function c is set. In one example, c is a function of edge e. The function c evaluated at an edge e is defined as c(e)=geometric length of FST edge e. An edge weight function c for the hypergraph H is then output as

c:E

[symbol]

[symbol]

or

Cϵ [symbol] ^{|E|}
where [symbol] is the set of real numbers.

Control then proceeds to step 240. In step 240, a function z is minimized subject to inequality constraints, where

$$z = c x ,$$

where z is a function of a dot product of c and x, and x is an optimization solution.

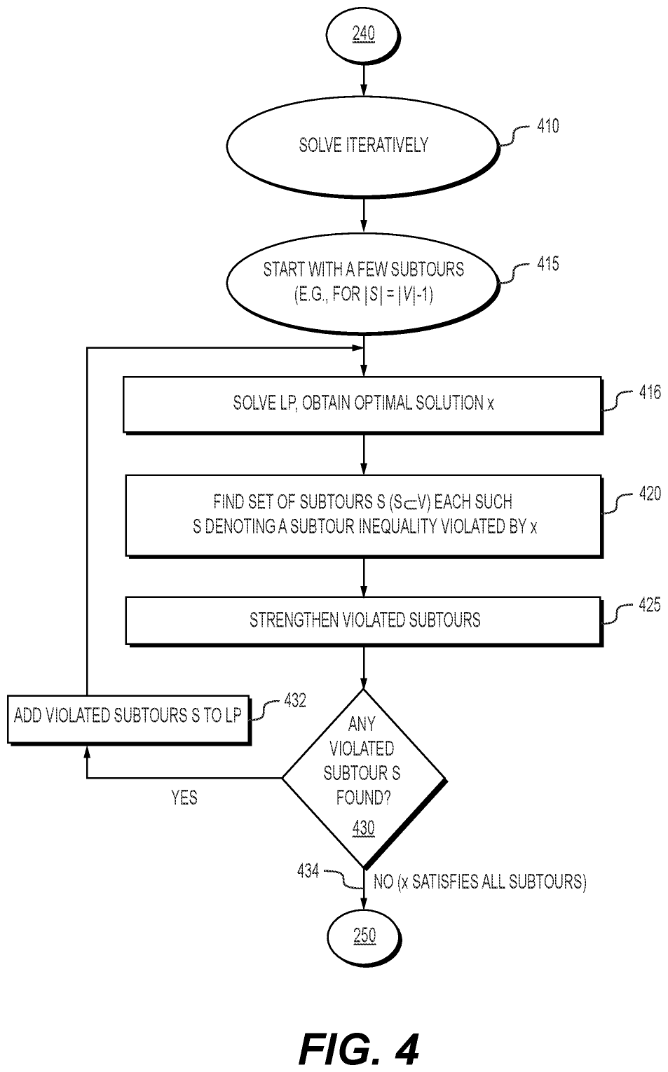

This minimization operation is described with respect to an example process shown in FIG. 4 that satisfies all subtour inequalities by iteratively adding inequalities (and in particular strengthened inequalities produced in step 425) that are violated by the current solution x. Further description in support of the operation in step 240 is provided below with reference to an underlying mathematical description and actual results obtained in test runs in an implementation.

FIG. 4 is a flowchart diagram showing in further detail iterative satisfaction of all subtours in step 240 of FIG. 2 according to an embodiment (steps 410-434). In one embodiment, augmenter 125 in graph concatenator 120 operates during step 425.

Loop 410 is carried out iteratively to solve and minimize the function z subject to a set of subtour inequalities. In step 415, the iterative loop is begun for a selected set of subtours (e.g., for |S|=|V|−1). The minimization of function z is carried out subject to a set of constraints (1)-(4):

$$Minimize : z = c \cdot x \\ Subject To : \\ {\sum }_{e ∈ E} ( \vert e \vert - 1 ) {x}_{e} = \vert V \vert - 1 , \qquad ( 1 )$$

$$\begin{matrix}{\sum }_{e ∈ E} max ( \vert e ⋂ S \vert - 1 , 0 ) {x}_{e} \leq \vert S \vert - 1 & ∀ S ⊂ V : \vert S \vert \geq 2 ,\end{matrix} \qquad ( 2 )$$

$$\begin{matrix}0 \leq {x}_{e} \leq 1 & ∀ e ∈ E ,\end{matrix} \qquad ( 3 )$$

$$\begin{matrix}{x}_{e} ∈ ℤ & ∀ e ∈ E .\end{matrix} \qquad ( 4 )$$

Constraint (1) ensures a relationship between the cardinalities of edges e and a set of vertices V for a solution x is met.

Constraints (2) are the subtour elimination constraints (or simply called subtours). Let S be a particular subset as specified in (2). Then the corresponding inequality from constraints (2) acts to prohibit cycles among the vertices of S.

Constraint (3) is set to keep a solution value xₑ bounded at or between 0 and 1.

Constraint (4) is set to ensure a solution value xₑ is an integer (that is an integer of a set of integers Z, positive or negative integers may be used.). This constraint may be omitted to allow a Linear Program (LP) to be used to get a solution and to allow the solution x to contain fractional values. Various embodiments, such as branch-and-bound or use of additional cutting planes can be used to resolve said fractional values into integral values satisfying constraint (4).

The operation of Constraint (1) can be further described with references to an example tree T. Consider a tree T having incidence vector x and (hyper) edge e, with |e|=k. Removing edge e splits T into k connected components (CCs), an increase of k−1 CCs. Removing all edges must increase from 1 CC to |V| CCs, a total increase of |V|−1 For example, FIG. 5B shows an example where an edge of cardinality five (shown in central region connecting a set of five terminal points) is removed, resulting in 5 CCs (570).

Let solution x designate a tree as follows:

$$x designates a tree ⇒ {\sum }_{e ∈ E} ( \vert e \vert - 1 ) {x}_{e} = \vert V \vert - 1.$$

For example, let T be any tree. Consider the sub-hypergraph of T induced by any subset S⊆V, where |S|=k, k≥2. The result is a forest of j trees, where 1≤j≤k, as shown in FIG. 5C (where j=2). FIG. 5C illustrates a tree 580 for which the subhypergraph induced by subset S of the vertices (582) is in general a forest of trees (2 in this example). Applying same counting argument to this sub-hypergraph yields this constraint:

$${\sum }_{e ∈ E} max ( \vert S ⋂ e \vert - 1 , 0 ) {x}_{e} = \vert S \vert - j .$$

This implies that for all x that represent trees,

$${\sum }_{e ∈ E} max ( \vert S ⋂ e \vert - 1 , 0 ) {x}_{e} \leq \vert S \vert - 1$$

Suppose that

$${\sum }_{e ∈ E} max ( \vert S ⋂ e \vert - 1 , 0 ) {x}_{e} > \vert S \vert - 1$$

This implies that there is a cycle contained entirely within S⊆V.

The inequalities:

$${\sum }_{e ∈ E} max ( \vert S ⋂ e \vert - 1 , 0 ) {x}_{e} \leq \vert S \vert - 1 \qquad ∀ S ⊂ V : \vert S \vert \geq 2$$

therefore prohibit cycles

As mentioned above, the above represents an example of Constraint (2) for subtour elimination constraints or “subtours” for short.

Given the above constraints, there is a one-to-one correspondence between the feasible solutions x of this integer program, and the spanning trees of the given hypergraph H. Also each feasible x is the incidence vector of a corresponding spanning tree. Objective coefficients can be any real value and there is no requirement that costs must be non-negative.

In step 416, a Linear Program (LP) is solved to obtain an optimal solution x subject to the current set of subtours.

When the vertices V of the edge-weighted hypergraph have been partitioned into two sets: the terminals T and the Steiner vertices N, the minimization function z is instead carried out subject to a set of constraints (5)-(11):

$$Minimize : z = c \cdot x + d \cdot y \\ Subject To : \\ {\sum }_{e ∈ E} ( \vert e \vert - 1 ) {x}_{e} = {\sum }_{v ∈ N} {y}_{v} + \vert V \vert - 1 , \qquad ( 5 )$$

$${\sum }_{e ∈ E} max ( \vert e ⋂ S \vert - 1 , 0 ) {x}_{e} \leq {\sum }_{v ∈ S ⋂ N} {y}_{v} + \vert S ⋂ T \vert - 1 \\ ∀ S ⊂ V : \vert S \vert \geq 2 , \vert S ⋂ T \vert > 0 , \qquad ( 6 )$$

$$\begin{matrix}{\sum }_{e ∈ E} max ( \vert e ⋂ S \vert - 1 , 0 ) {x}_{e} \leq {\sum }_{u ∈ S - \{ v \}} {y}_{u} & ∀ v ∈ S ⊆ N : \vert S \vert \geq 2 ,\end{matrix} \qquad ( 7 )$$

$$\begin{matrix}0 \leq {x}_{e} \leq 1 & ∀ e ∈ E ,\end{matrix} \qquad ( 8 )$$

$$\begin{matrix}0 \leq {y}_{v} \leq 1 & ∀ v ∈ N ,\end{matrix} \qquad ( 9 )$$

$$\begin{matrix}{x}_{e} ∈ ℤ & ∀ e ∈ E ,\end{matrix} \qquad ( 10 )$$

$$\begin{matrix}{y}_{v} ∈ ℤ & ∀ v ∈ N .\end{matrix} \qquad ( 11 )$$

The x variables indicate which edges are in the optimal tree.

The y variables indicate which Steiner vertices are in the optimal tree.

Constraint (5) ensures a relationship between the cardinalities of edges e and a set of vertices V for a solution x,y is met.

Constraints (6) prohibit cycles among a set S of vertices containing at least one terminal vertex.

Constraints (7) prohibit cycles among a set S consisting solely of Steiner vertices.

Constraint (8) is set to keep a solution value xₑ bounded at or between 0 and 1.

Constraint (9) is set to keep a solution value yᵥ bounded at or between 0 and 1.

Constraint (10) is set to ensure a solution value xₑ is an integer (that is, a member of the set Z of integers).

Constraint (11) is set to ensure a solution value yᵥ is an integer (that is, a member of the set Z of integers).

Constraints (10) and (11) may be omitted to allow a Linear Program (LP) to be used to get a solution and to allow solution x.y to have fractional values. Various embodiments, such as branch-and-bound or use of additional cutting planes can be used to resolve said fractional values into integral values satisfying constraints (10) and (11).

Constraints (6) and (7) together comprise the subtour elimination constraints (called “subtours” for short) of this formulation.

In step 420, a set of subtours S are found. For example, concatenator 120 finds one or more subtours S (S⊂V) where each such S denotes a subtour inequality violated by x (or x,y). When satisfaction of all subtour inequalities is required, step 420 must find at least one violated S, if any exist.

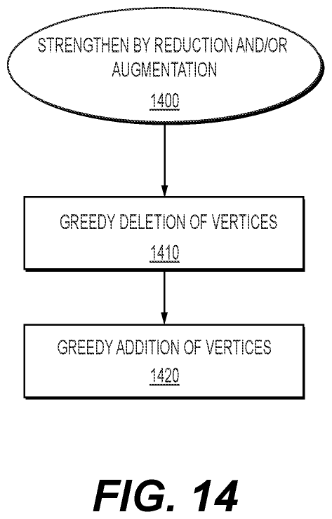

In step 425 each violated inequality is strengthened as described below with respect to FIGS. 5A and 14.

In step 430, a check is made on whether any violated subtours are found. If yes, each violated subtour S is added to the LP (step 432), and control proceeds to step 416 to solve the LP using the added violated subtours. If no, then the solution x (or x,y) satisfies all subtours and control proceeds to step 250 or end.

In step 432, control proceeds to add each violated subtour S to the LP instance operated upon by subsequent iterations of step 416.

FIG. 5A is a diagram showing a method of augmentation 500 having different routines for augmenting subtours to strengthen a violated inequality according to embodiments (steps 510-560). In step 510, augmenter 125 augments a subtour (S) with one or more vertices. This augmentation may be carried out in one or more ways or combinations of ways.

As shown in FIG. 5A, augmentation may include adding vertices to a subtour in a hypergraph formed from the initial set of trees (step 520). Augmentation may also include performing a single vertex augmentation to a subtour (step 530) or performing a greedy augmentation of subtour inequalities by repeatedly performing single vertex augmentation to a subtour (step 540). Augmentation may also include adding complementary connected components to a subtour (step 550) or adding complementary biconnected components to a subtour (step 560).

In sum, relaxing the integrality constraints (e.g., Constraint (4) or Constraints (10) and (11)) yields a Linear Program to solve. However, there can be exponentially many subtour constraints. Loop 410 then provides a solution by solving selected subtours iteratively. For instance, solve iteratively as follows:
start with just a few subtours (e.g., for |S|=|V|−1);
solve a LP, giving optimal solution x;
find S⊂V for which x violates corresponding subtour inequalities (the so-called “separation” problem). When satisfaction of all subtours is required, this step must find at least one such S if any exist; and
add violated subtours to LP and re-solve until x satisfies all (exponentially many) subtours.

In this example, an optimal LP solution x (or x,y) may be fractional. Control may resolve to integral via branch-and-bound, adding violated subtours (as needed) at each branch-and-bound node Additional cutting planes can also be used to achieve integer solutions. Any integer solution discovered is an upper bound on an optimal solution. Integer solution values are feasible, but not necessarily optimal. In one option, only the lowest of these upper bounds are kept. Branching slowly increases the lower bound. When the lower bound equals the upper bound, the current best solution (upper bound) has been proven to be optimal.

### Strengthening Violated Subtour Inequalities Examples

Another way to consider solutions described herein to the separation problem for subtour inequalities (as performed by step 420) is as follows:
We are given xϵ [symbol] ^{|E|}.
Find S⊂V, |S|≥2 such that

$${\sum }_{e ∈ E} max ( \vert S ⋂ e \vert - 1 , 0 ) {x}_{e} > \vert S \vert - 1 ,$$

or show that no such S exists.

All known embodiments of step 420 are computationally expensive. The common embodiments require n−1 maximum s−t flows on a network typically O(n) in size, where n=|V|. The Dinic algorithm is O(n³), making this step O(n⁴). It is therefore advantageous to reduce the size of instances processed by step 420, as described below.

Another option is to reduce the size of separation instance prior to applying a main separation algorithm as follows:
reduce size of separation instance prior to applying main separation algorithm:

$$For all v ∈ V , define {b}_{v} = {\sum }_{e ∈ E : v ∈ e} {x}_{e} . \\ Let S = T ⋃ \{ v \} .$$

If S contains a violation and bᵥ≤1, then T contains a violation.

Iteratively discard vertices v such that bᵥ≤1.

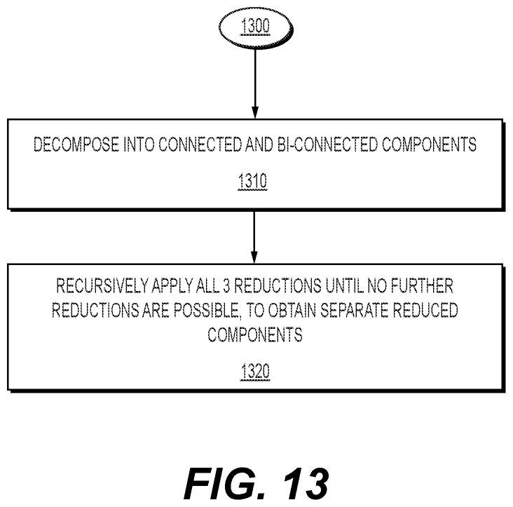

As shown in FIG. 13, reduction operation 1300 may be done (steps 1310-3120). In step 1310, a hypergraph being processed by concatenator 120 (as in step 420) can decompose into connected and bi-connected components. Also,

Bi-connected components can reveal more bᵥ≤1 reductions

Accordingly, concatenator 120 can recursively apply all 3 reductions until no further reductions are possible, to obtain separate reduced components (step 1320).

After these reductions, concatenator 120 can perform separation step 420 independently on each reduced component.

Let x be an LP solution, and S be a violated subtour from flow algorithm (in step 420):

Resulting S often has lots of “noise” (e.g., numerous optimal flow solutions);

Strengthening by reduction: Consider the weighted sub-hypergraph H induced by S:

Perform all reductions on H; and

Resulting violations S1, S2, . . . , Sj, are usually much smaller, stronger subtour inequalities.

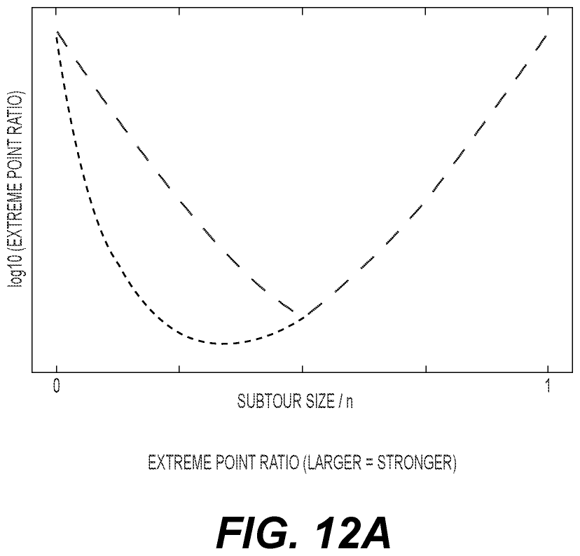

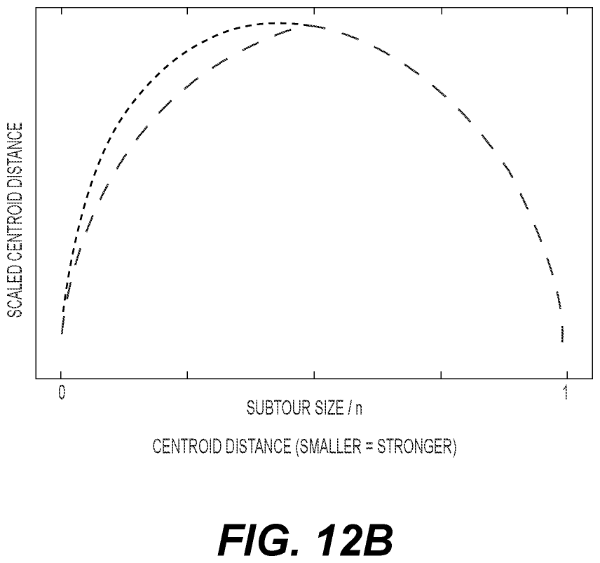

In some applications it is helpful to choose particular violations S in steps 420 and 425 so that loop 410 terminates quickly (with few iterations). For example, “strong” constraints tend to converge quickly, whereas “weak” constraints tend to converge slowly. As discussed further below, FIGS. 12A and 12B show how large subtours can be even stronger than small subtours according to two metrics, EPR and CD.

One feature of embodiments described herein is to strengthen violated inequalities by running the reductions in reverse. In other words, to augment violated subtours S instead of reducing them. This includes existing reductions, such as, greedy deletion of vertices, connected components, and biconnected components, which are applied recursively until no more reductions are possible.

In addition, this feature of embodiments includes for the first time running each of these three reduction methods conceptually in reverse (augmentation). As shown in routine 1400 of FIG. 14, this augmentation can include: (i) greedy deletion of vertices (step 1410):

$$For all v ∈ V , let {b}_{v} = {\sum }_{e ∈ E : v ∈ e} {x}_{e}$$

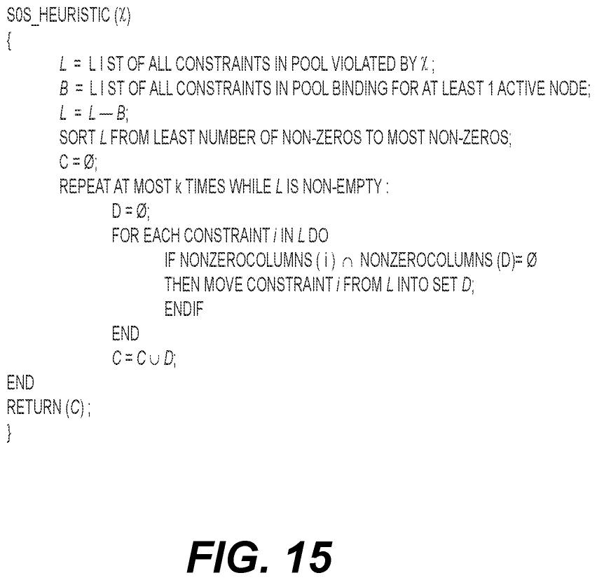

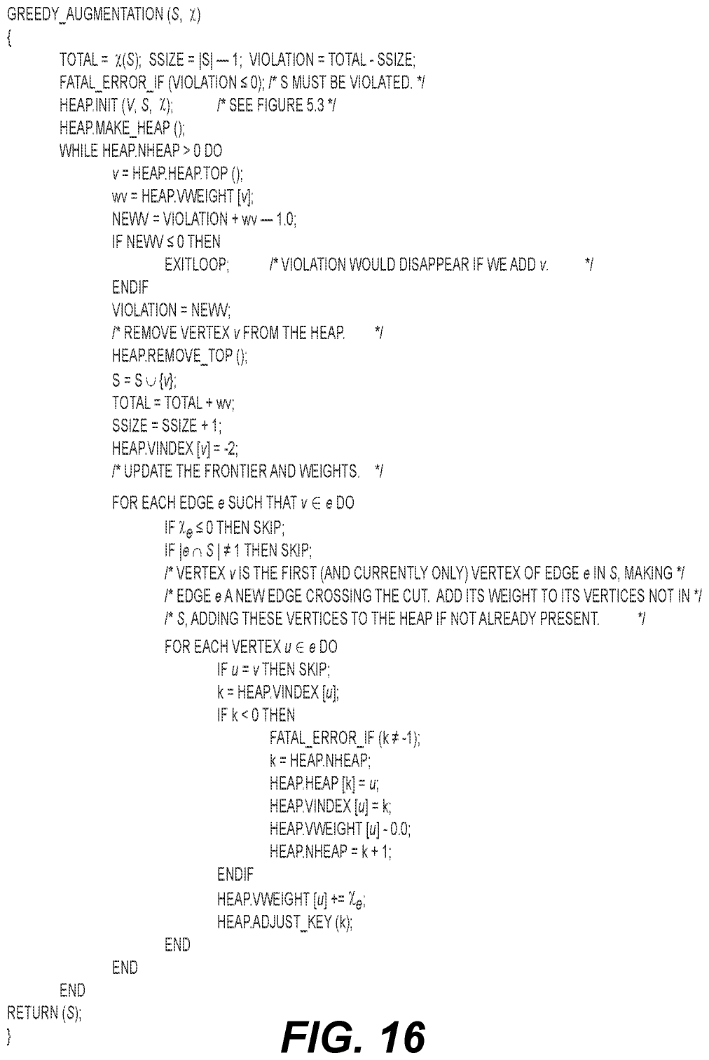

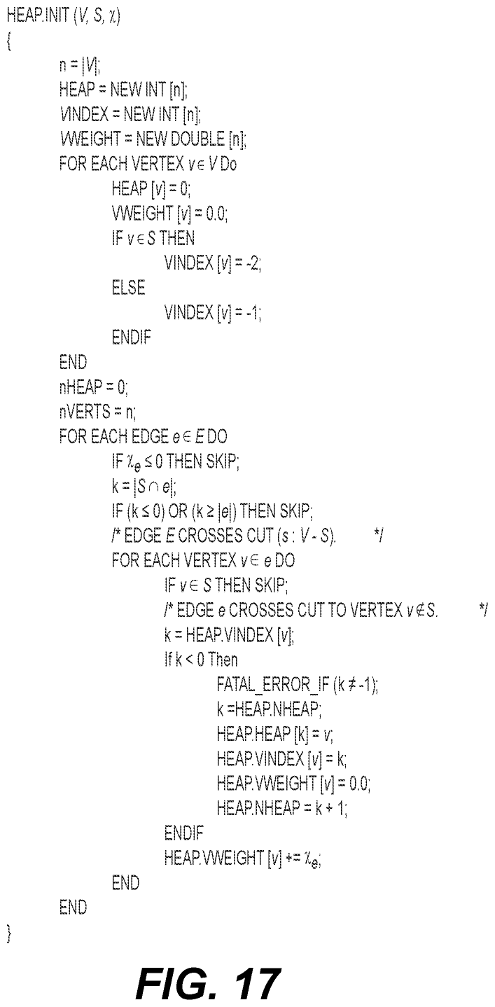

Iteratively delete vϵS such that bᵥ≤1; and
(ii) greedy addition of vertices (step 1420)
Iteratively add vertices vϵV−S such that x(S:{v})≥1
Efficient heap-based O(n log(n)) algorithm
with example embodiment shown in FIGS. 16 and 17; or
(iii) running connected components in reverse:
Let S be a violated subtour
Let H̅ be the subhypergraph induced by V−S
Let the connected components of H̅ be H₁, H₂, . . . , Hₖ
Let Sᵢ=V−Hᵢ for all 1≤i≤k

Then at least one of the Sᵢ is a violated subtour

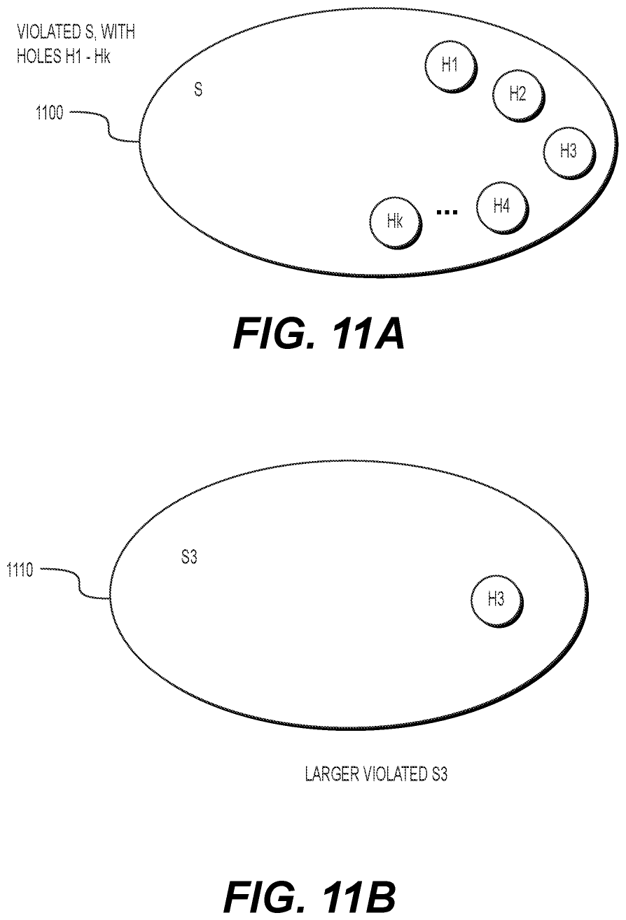

FIG. 11A illustrates graphically a violated subtour S 1100 with multiple holes (H1-Hk) in augmentation of connected components including running connected components in reverse according to an embodiment. FIG. 11B illustrates graphically a larger violated subtour S3 1110 compared to a relatively smaller violated subtour S (from FIG. 11A) according to an embodiment.

When the vertices V of the edge-weighted hypergraph have been partitioned into two sets: the terminals T and the Steiner vertices N, the processes used for reduction are very similar, as should be apparent to a person skilled in the art. The rules for single-vertex augmentation in this case, are also very similar: a vertex vϵT can be added to S whenever x(S:{v})≥1: a vertex vϵN can be added to S whenever x(S:{v})≥yᵥ. The processes for strengthening by complementary connected components and complementary biconnected components remain the same whether V is (or is not) partitioned into terminals T and Steiner vertices N.

### Computational Results and Technical Improvement

The inventors carried out operations in an example implementation of graph engine 102 as described above to obtain remarkable results.

### 100,000 Point Set Test

In one test, 15 random point sets of 100,000 points each were used as instances of a terminal point set T and applied from storage device 106 to graph engine 102. The 100,000 point sets were the same or similar to those identified in Juhl, Warme, Winter, Zachariasen 2018. In the test, graph engine 102 was implemented as a GeoSteiner software package modified to support graph concatenation with augmentation to strengthen violated subtour inequalities as described herein. The new modified GeoSteiner software package was run on a computing device made up of an AMD Ryzen 2950X Threadripper with 128 Gb of 3200 MHz DDR4 DRAM with ECC running CENTOS 7 and CPLEX 12.5.

In the test, all 15 instances were solved with fast solution times. In particular, solution times of approximately 12 to 24 CPU minutes each were obtained. In contrast, an earlier instance run using a conventional GeoSteiner software package (version 5.0.1) which did not include concatenation with augmentation to strengthen violated inequalities as described herein was applied to one large 100,000 point instance and still did not reach a solution after running more than 2.75 CPU years on a 5.0 GHZ AMD 9590 It is noteworthy that the results using augmentation were not just fast but had very low variance in compute time, whereas results without augmentation have extremely high variance in compute time.

Additional tests also were carried out which obtain relatively fast solutions as follows for random terminal point sets having the following sizes: Euclidean SMTs were obtained for a 250,000 terminal instance, a 500,000 terminal instance, and even a 1,000,000 terminal instance. In addition, a rectilinear SMT was obtained for an instance with 40,000 terminals. All of these results lie completely beyond the reach of prior art.

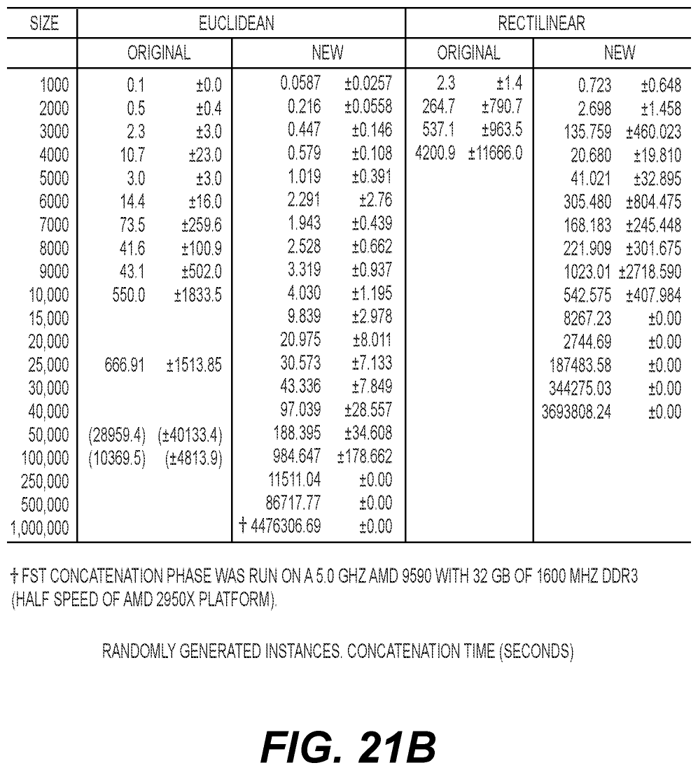

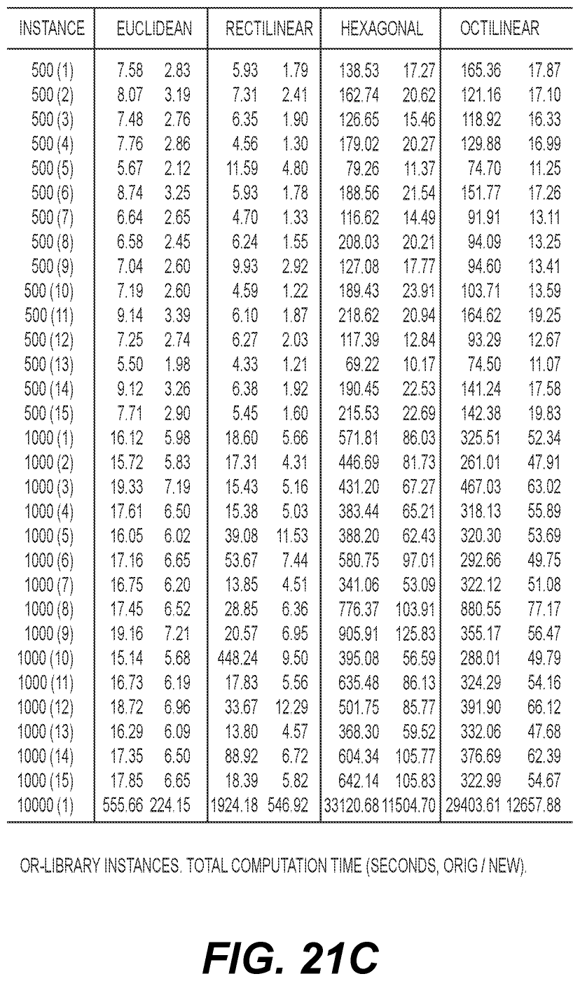

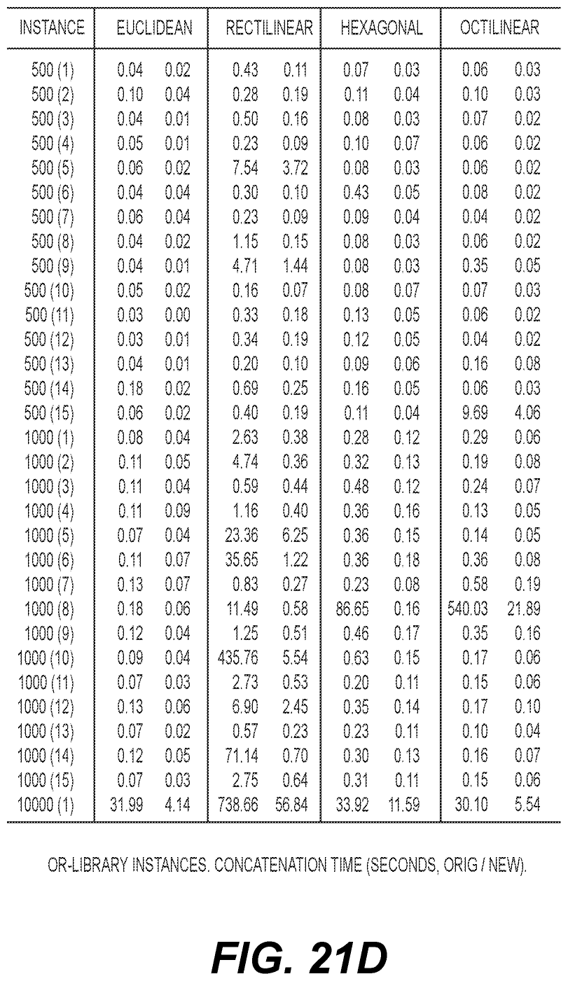

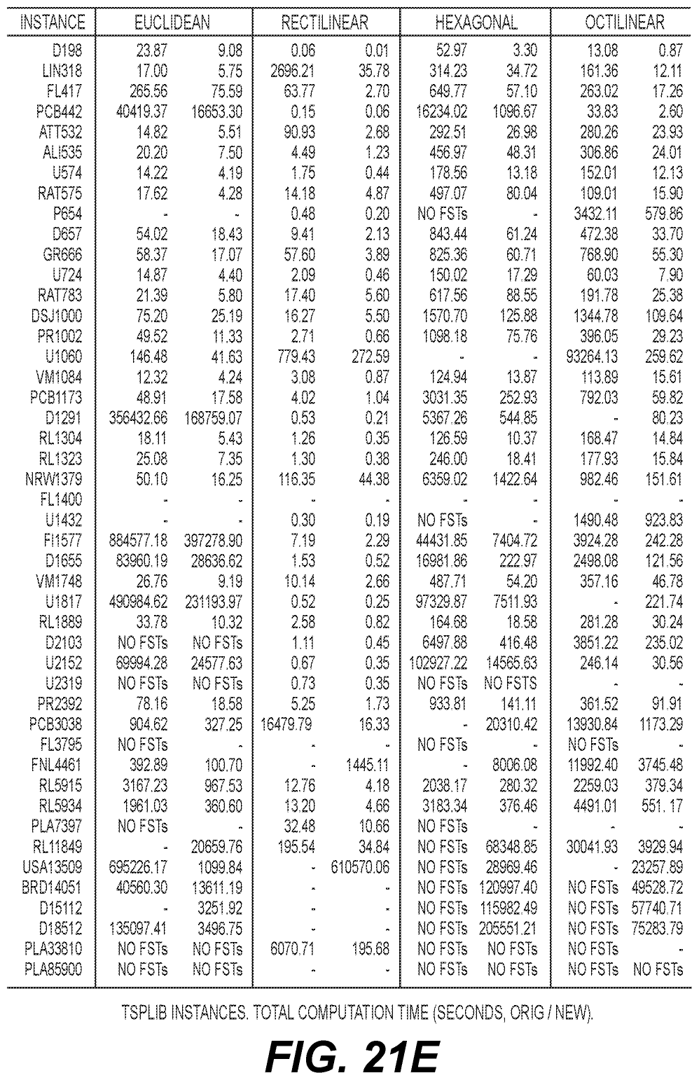

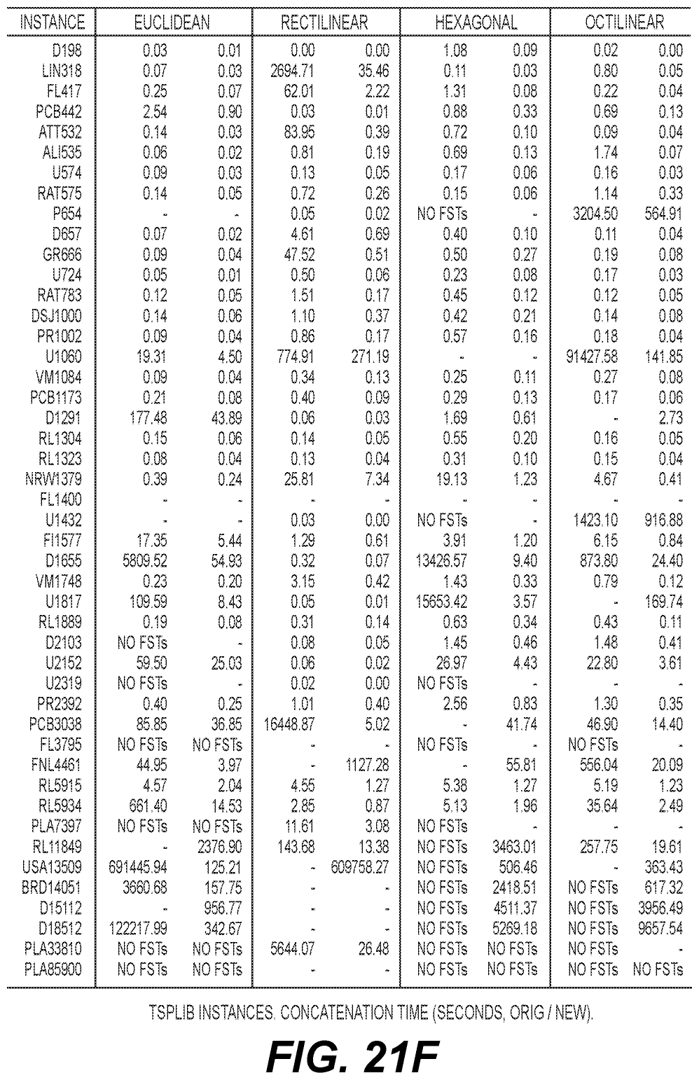

FIGS. 21A, 21B, 21C, 21D, 21E and 21F show tabulated results for example terminal set instances processed with augmentation that adds one or more vertices to strengthen one or more violated subtour inequalities (S) according to embodiments. In each of these test results, Original computation results were obtained using a conventional GeoSteiner software package (version 5.0) which did not include concatenation with augmentation to strengthen violated inequalities as described herein. New computation results were obtained using a graph engine 102 implemented as a GeoSteiner software package modified to support graph concatenation with augmentation to strengthen violated subtour inequalities as described herein. The new modified GeoSteiner software package was run on a computing device made up of an AMD Ryzen 2950X Threadripper with 128 Gb of 3200 MHZ DDR4 DRAM with ECC running CENTOS 7 and CPLEX 12.5.

FIG. 21A shows the total time taken to obtain results in tests carried out for a set of randomly generated instances. The instance size (number of terminal points) ranged from 1000 to 1,000,000 as shown in the left column. Two types of Full Steiner Tree (FST) processing were used: Euclidean and Rectilinear. (See middle and right columns in Table, row 1). For comparison, both Original and New computation results are presented for both Euclidean and Rectilinear Steiner trees. The computation results show the total computation needed to obtain a SMT solution for the respective point set in CPU time (CPU time in seconds). As shown in the FIG. 21A table, for each of the instance sizes in Table 21A, New computation results were obtained that were significantly faster than Original results. For example. New computation results for 1000 terminal instances were obtained using Euclidean FSTs in about 6.52 seconds compared to Original results time of about 17.2 seconds as shown in the table (in other words, about a 263% performance improvement). Performance also improved for Rectilinear FSTs. New computation results for 1000 terminal instances were obtained using Rectilinear FSTs in about 5.25 seconds compared to Original results time of about 16.1 seconds as shown in the table (in other words, about a 306% performance improvement). Performance improvements are also evident for other instance sizes. In some results, New computation results were obtained (that is, optimal solutions found for all instances), when Original results failed to solve all instances within 7 CPU days (as shown for example in parentheses around Original Euclidean 50,000 and 100,000 point sets). Note that the FST concatenation phase for the 1,000,000 point Euclidean instance was run on a 5.0 GHZ AMD 9590 processor with 32 GB of 1600 MHZ DDR3 with ECC (half speed of AMD 2950X platform).

FIG. 21B shows the total time taken to run a FST concatenation phase on the same randomly generated instances as in FIG. 21A. This comparison further illustrates significant performance advantages obtained between New and Original results. Note that the FST concatenation phase for the 1,000,000 point Euclidean instance was run on a 5.0 GHZ AMD 9590 processor with 32 GB of 1600 MHZ DDR3 with ECC (half speed of AMD 2950X platform).

For example, New computation results for the FST concatenation phase for 1000 terminal instances were obtained using Euclidean FSTs in about 0.0587 seconds compared to Original results time of about 0.1 seconds as shown in the table (in other words, about a 170% performance improvement). Performance also improved for Rectilinear FSTs in FST concatenation. New computation results for 1000 terminal instances were obtained using Rectilinear FSTs in about 0).723 seconds compared to Original results time of about 2.3 seconds as shown in the table (in other words, about a 318% performance improvement). Performance improvements are also evident for other instance sizes. In some results, New computation results were obtained (that is, optimal solutions found for all instances), when Original results failed to solve all instances within 7 CPU days (as shown for example in parentheses around Original Euclidean 50,000 and 100,000 point sets).

FIG. 21C and FIG. 21D show further results of the time taken to process instances drawn from the OR-Library suite of benchmark instances (OR-Library instances). FIG. 21C shows performance improvements obtained in the total computational time in seconds between tests on New and Original implementations and for Euclidean, Rectilinear, Hexagonal and Octilinear trees. FIG. 21D shows performance improvements obtained in the concatenation computational time in seconds between tests on New and Original implementations and for Euclidean, Rectilinear, Hexagonal and Octilinear trees.

Similarly, FIG. 21E and FIG. 21F shows further results of the time taken to process instances drawn from the TSPLIB suite of benchmark instances (TSPLIB instances). FIG. 21E shows performance improvements obtained in the total computational time in seconds between tests on New and Original implementations and for Euclidean, Rectilinear, Hexagonal and Octilinear trees. FIG. 21F shows performance improvements obtained in the concatenation computational time in seconds between tests on New and Original implementations and for Euclidean, Rectilinear, Hexagonal and Octilinear trees.

### Further Discussion

The inventors apply several metrics to provide a quantitative measure of the relative strength of inequalities with respect to a given polytope. These metrics depend only upon the inequality and the underlying polytope, and are independent of the objective function. The inventors evaluated two metrics (the extreme point ratio (EPR) and centroid distance (CD)) in closed form for various facet classes of both the traveling salesman polytope TSP(n), and the spanning tree in hypergraph polytope STHGP(n). The inventors found the two metrics are in good agreement regarding the relative strength of facets in each class, and corroborate previous computational experience with both polytopes. For STHGP(n), the inventors found both metrics clearly indicate that subtours of small and large cardinality are strong, while those of medium cardinality are significantly weaker. Both metrics, however, also agree that subtours of large cardinality are significantly stronger than those of small cardinality. This property of STHGP(n) was neither known nor suspected until clearly revealed by these metrics as discovered by the inventors. See, inventors' commonly-owned U.S. Provisional Applications No. 63/245,326, filed Sep. 17, 2021, and 63/225,111, filed Jul. 23, 2021 (each incorporated by reference herein in its entirety).

In an embodiment, the inventors further exploited this previously unknown property algorithmically within a graph engine 102 implemented using a modified GeoSteiner software package program as described herein. The inventors obtained strong computational evidence that the EPR and CD metrics are highly predictive of actual computational strength, at least for subtour inequalities of STHGP(n).

Conventional GeoSteiner software packages (version 5.1 and earlier) for geometric Steiner trees in the plane use STHGP(n) to solve the Full Steiner Tree (FST) concatenation problem. The separation algorithms in conventional versions of GeoSteiner packages find violated subtours of only relatively small cardinality.

The inventors examined the underlying algorithmic causes and present improvements to a GeoSteiner software package which are specifically designed to strengthen violated subtours by augmentation (instead of reduction alone), yielding violated subtours of large cardinality. The computational results are stunning.

The inventors have also evaluated (in closed form) the EPR and CD metrics for subtour inequalities of the Steiner tree in “conventional” graphs polytope, and the EPR metric for subtour inequalities of the Steiner tree in hypergraph polytope. The resulting metrics are functions f(n,m,p,q), where n is the number of terminals in the graph/hypergraph, m is the number of Steiner vertices in the graph/hypergraph, p is the number of terminals in the subtour, and q is the number of Steiner vertices in the subtour. Note that plotting any function over a 4-dimensional domain is challenging. However, several creative ways have been used to project such 5-dimensional plots down to two dimensions. The resulting curves are strikingly similar to those for the subtours of the spanning tree in hypergraph polytope STHGP(n). The differences between terminals and Steiner vertices can be discerned in small graphs/hypergraphs (those having few vertices), but these differences become asymptotically insignificant in larger graphs/hypergraphs (having many vertices). The inventors have performed computational experiments using an experimental embodiment of GeoSteiner modified to solve the Steiner tree in hypergraphs problem (which can therefore also be used to solve conventional Steiner tree in graph instances). Computational tests on the B, C, D and E instances (Steiner problem in graphs) from the OR-Library show similar speedups (to those tabulated herein for the spanning tree in hypergraph problem) before/after using augmentation to strengthen violated subtour inequalities. Since this experimental code performs no reductions on these instances prior to invoking the branch-and-cut, solution times for these experiments were not competitive with state-of-the-art, so we omit empirical details of these computational experiments. This demonstrates that the ability of the EPR and CD metrics to quantitatively model and predict actual computational strength successfully translates to other polytope/inequality combinations.

One conclusion of inventors is that the EPR and CD strength metrics have incredible predictive power regarding actual computational strength, at least regarding STHGP(n). The ability to accurately measure the strength of inequalities has numerous applications of great importance, both in theory and practice.

The inventors reviewed several metrics that provide a quantitative measure of the relative “strength” of inequalities with respect to a given polytope. These metrics are functions m:(H, P)→R+, where H is the hyperplane corresponding to a given linear inequality, and P is a polytope. Let X be the set of all extreme points of polytope P. The extreme point ratio (EPR) metric is |H∩X|/|X|, for which larger ratios indicate stronger inequalities. The centroid distance (CD) metric measures the distance between the centroid C=(1/|X|)ΣxϵX x and H, for which shorter distances indicate stronger inequalities. (There are two versions of metric CD: the “weak” CD measures distance along a line residing entirely within the affine hull of P. The “strong” CD measures distance along a line residing entirely within P.)

Closed forms were obtained for both the EPR and CD metrics applied to the subtour inequalities of the Spanning Tree in Hypergraph Polytope (STHGP). See described in inventors' provisional applications U.S. Provisional Application No. 63/245,326, filed Sep. 17, 2021, and 63/225,111, filed Jul. 23, 2021, each of which is incorporated by reference herein in its entirety. FIG. 12A presents a plot of the EPR metric with n=1000 (the bottom-most curve in smallest dashes line). FIG. 12B presents a plot of the CD metric with n=1000 (the top-most curve in smallest dashes line). It was known that subtours of small cardinality were computationally very strong, and both metrics confirm this. Both metrics, however, also agree that subtours of large cardinality (i.e., containing a large fraction of all vertices) are even stronger than subtours of small cardinality. This is illustrated in FIGS. 12A and 12B in which the right half of each curve has been reflected onto the left half. The vertical region between the small dash and large dash line curves indicates how much stronger the large subtours are than the corresponding small subtour. This property was neither known, nor suspected until revealed by the metrics in the inventors' work, and suggests that adding violated subtours S to the LP, where |S| is large, could significantly speed up computations by reducing the number of optimize-separate iterations needed to satisfy all of the subtour inequalities, as in FIG. 4.

In test runs, the inventors tested these aspects computationally within a GeoSteiner software package, which has been the fastest software in existence for solving geometric Steiner trees in the plane since 1998. See. D. Juhl. D. M. Warme. P. Winter. and M. Zachariasen. The GeoSteiner Software Package for Computing Steiner Trees in the Plane: An Updated Computational Study. Math Programming Computation. 10:487-532, 2018; and David M. Warme. Spanning Trees in Hypergraphs with Applications to Steiner Trees. PhD thesis. Department of Computer Science. University of Virginia. Charlottesville. Virginia. 1998.

In this example discussion, the inventors define notation below. We outline the major algorithmic phases of an example improved GeoSteiner software package embodiment having the features described herein (also called a test GeoSteiner system or test version of GeoSteiner software). The algorithmic forces operating within the test GeoSteiner system are described that cause it to effectively find only violated subtours S of relatively small cardinality. Modifications made in the test GeoSteiner system with respect to conventional GeoSteiner software subtour separation and constraint strengthening algorithms are described. These modifications in this embodiment intentionally target subtours of large cardinality to exploit their superior strength, as predicted by both EPR and CD metrics. To inventors' knowledge no motivation for such modifications existed prior to the inventors' discovery of the insight these metrics provided. The description presents computational results for the test GeoSteiner system. These results provide truly stunning improvements over those previously reported in D. Juhl. D. M. Warme. P. Winter, and M. Zachariasen. The GeoSteiner Software Package for Computing Steiner Trees in the Plane: An Updated Computational Study. Math Programming Computation, 10:487-532, 2018. This provides compelling computational evidence that the EPR and CD metrics are highly predictive of actual computational strength, at least regarding the subtours of STHGP. The inventors also discuss various ramifications and applications of these results. References to “we” in these sections refer to the inventors.

### Notation

We define R to be the real numbers, and Z to be the integers. A hypergraph H=(V, E) consists of a finite set V of vertices, and a set E of edges. Each edge eϵE satisfies e⊆V and |e|≥2. Let m=|E| and xϵR^{m}. For S⊆V and T⊆V−S we define

$$x ( S ) ≡ {\sum }_{e ∈ E} max ( \vert e ⋂ S \vert - 1 , 0 ) {x}_{e} , \\ x ( S : T ) ≡ {\sum }_{\begin{matrix}e ∈ E : \\ ( e ⋂ S \neq ∅ ) ∧ ( e ⋂ T \neq ∅ )\end{matrix}} {x}_{e} .$$

The first of these gives the total “edge material” that x contains within subset S (i.e., counting k vertices of edge e as being equivalent to k−1 conventional graph edges within S, where k=|e∩S|). The second of these gives the total weight of edges crossing cut (S:T).

Given a hypergraph H=(V, E) and an xϵR^{|E|}, we define the support hypergraph of H to be the hypergraph H′=(V, E′), where E′={eϵE:xₑ>0}.

### Example GeoSteiner Algorithmic Overview

The test GeoSteiner software computes a geometric Steiner tree in two main phases. Given a finite set T of terminals in R², the “FST Generation” phase computes a “sufficient” set F of Full Steiner Trees. A Full Steiner Tree t is a geometrically embedded tree such that: (1) t connects some subset U⊆T, (2) |U|≥2, (3) terminals appearing in t are all leaves of t (degree 1), (4) all non-leaf vertices in t (Steiner vertices) are interior nodes of T (degree >1), and (5) t is locally optimal. The set F is “sufficient” in that it guarantees that an optimal Steiner tree exists as the concatenation of some subset F′⊆F of FSTs. A completely different algorithm is used for each supported distance metric M (based upon a corresponding “structure theorem” for M), and implicitly considers all possible subsets U of T, and all possible tree topologies over U, discarding only combinations that can be proven to be sub-optimal or redundant. Although this can give rise to an exponentially large set of FSTs, most point sets “in general position” yield only O(n) FSTs for n given terminals. Despite the large space that is implicitly enumerated, GeoSteiner's FST generation algorithms are surprisingly efficient. For “well behaved” point sets yielding a linear number of FSTs, these algorithms empirically run in approximately O(n^{2.5}) time. This success notwithstanding, there are point sets that do provoke bad behavior. For the Euclidean distance metric, points lying on regular integer grids give rise to an exponential number of FSTs. See, E. J. Cockayne and D. E. Hewgill, “Improved computation of plane Steiner minimal trees,” Algorithmica, 7:219-229, 1992; and P. Winter and M. Zachariasen, “Euclidean Steiner minimum trees: an improved exact algorithm,” Networks, 30:149-166, 1997. For the rectilinear metric there is a known “fractal” pattern of terminals that yields an exponential number of FSTs. See, U. Fößmeier and M. Kaufmann, “Solving rectilinear Steiner tree problems exactly in theory and practice,” Proceedings of the European Symposium on Algorithms, 1997.

During the second “FST concatenation” phase, the terminals T and the set F of FSTs are input to step 120 of the test GeoSteiner system. The goal is to identify a subset Y⊆F such that the FSTs Y form a tree that spans all terminals T having minimum total length.

Between these two phases is an optional “FST pruning” phase that uses global information about the entire set of FSTs to: (1) discard FSTs that can be proven to be sub-optimal, and (2) mark some of the remaining FSTs to be “required,” i.e., such FSTs must be present in any optimal Steiner tree. FST pruning can significantly reduce the size and difficulty of the subsequent FST concatenation problem.

The test GeoSteiner system reduces its Full Steiner Tree (FST) “concatenation” phase to the problem of finding a minimum spanning tree in a hypergraph H=(V, E) with given vector c of edge weights. The hypergraph is constructed by trivially setting V=T, and for each FST t⊆F, there is a corresponding edge eϵE whose vertices consist of the terminals appearing in t, and whose edge weight cₑ is the geometric length of t, as measured in the appropriate distance metric. (The edges E contain only terminals—the interior Steiner vertices of the FST are abstracted away in the resulting hypergraph.) GeoSteiner then uses branch-and-cut to find a Minimum Spanning Tree in Hypergraph H using the following integer program:

$$Minimize : c \cdot x \qquad ( 3.1 )$$

$$Subject To : \\ x ( V ) = \vert V \vert - 1 , \qquad ( 3.2 )$$

$$x ( S ) \leq \vert S \vert - 1 for all S ⊂ V such that \vert S \vert \geq 2 , \qquad ( 3.3 )$$

$${x}_{e} ∈ \{ 0 , 1 \} for all e ∈ E . \qquad ( 3.4 )$$

Equation (3.2) requires the proper number and cardinality of edges needed to form a tree. Analogous to Kruskal's algorithm for MST in conventional graphs, adding an edge e of cardinality k=|e| (when e does not form a cycle) replaces k connected components with 1 connected component, reducing the number of connected components by k−1. This equation requires the total number of connected components to drop by |V|−1. Constraints (3.3) are the subtour inequalities, which operate similarly within a subset S of the vertices, except that they place only an upper bound on the drop in number of connected components-within S. It is proven in [6] that the integer feasible solutions of this integer program are identically the incidence vectors of all spanning trees of H. This correspondence is independent of c, which can therefore be any vector in R^{|E|}.

### Test GeoSteiner System Finds Only Small Cardinality Subtours

The algorithms used to separate and strengthen subtour inequalities (3.3) in conventional GeoSteiner versions 5.1 and earlier are in most cases incapable of finding violated subtours S of large cardinality, i.e., containing a large fraction of the vertices. (The special case where the support hypergraph consists of two or more connected components is the major exception. For each connected component S⊂V, GeoSteiner generates subtours for both S and V−S, one of which is probably small and the other probably large.) GeoSteiner's main separation algorithm for subtour inequalities is described in David M. Warme, Spanning Trees in Hypergraphs with Applications to Steiner Trees, PhD thesis, Department of Computer Science, University of Virginia, Charlottesville, Virginia, 1998. Given a support hypergraph H=(V, E) with edge weights x, it finds an S⊆V such that subtour S maximally violates x. It reduces this to at most |V|−1 maximum s−t flow computations in an acyclic flow network having |V|+|E|+2 vertices and |V|+[E]+Z_{eϵE}|e| directed arcs.

For all of the distance metrics supported by a GeoSteiner system, there is a small, fixed integer k (e.g., k=15 usually suffices) such that the number of terminals in a single FST is at most k (with high probability) over all “well behaved” point sets (i.e., “in general position”). Furthermore, as mentioned previously, we usually have |E|=O(|V|). This means that the flow network is usually of size O(n), where n=[V].

Solving flow problems can be computationally expensive. Conventional GeoSteiner software uses the relatively simple Dinic algorithm, which runs in strongly polynomial time. Under the conditions above, it runs in O(n³) time. Since we must solve up to n−1 of these s−t flow problems, the entire separation algorithm has complexity O(n⁴). When using an algorithm this costly, it is advantageous to perform various reductions on the support hypergraph H to assure that the expensive flow separator is invoked only on instances that are as small as possible.

For all vϵV, we define

$${b}_{v} = x ( \{ v \} : V - \{ v \} ) . \\ {b}_{v} = x ( \{ v \} : V - \{ v \} ) . \qquad ( 4.1 )$$

We call bᵥ the “congestion level” of vertex v. For all S⊂V with S≥2 we define f(S)=|S|−x(S), so that f(S)≤1 implies that the corresponding subtour inequality (3.3) is violated.

The following reduction lemmas were proven in the 1998 D Warme thesis:

Lemma 4.1 Let xϵR^{|E|}, U⊂V such that |U|≥2, and vϵV−U.
If bᵥ≤1 and f (U∪U{v})<1 then f(U)<1.

Thus vertices v such that bᵥ≤1 can be iteratively eliminated from the support hypergraph until no such vertices remain. If the original hypergraph contains a violated subtour, then the reduced hypergraph must also contain a violated subtour.

Lemma 4.2 Let H=(V, E) be a hypergraph with weights xₑ for all eϵE. Let H̅=(V, Ē) be the support hypergraph of H. Let the connected components of H̅ be H₁=(V₁, E₁), H₂=(V₂, E₂), . . . , Hₖ=(Vₖ, Eₖ). Let S⊆V and Sⱼ=S∩Vⱼ for all 1≤j≤k. If f(S)<1 then there is some j such that f(Sⱼ)<1.
Lemma 4.3 Let H=(V, E) be a hyper graph with weights xₑ for all eϵE. Let H̅=(V, Ē) be the support hypergraph of H. Let A, B, C be a partition of V and E_{A}, E_{B} be a partition of E such that |C|=1, E_{A}={eϵĒ:e⊆(AUC)} and E_{B}={eϵĒ:e⊆(B∪C)}. If S⊂V such that f(S)<1 then f(S∩(A∪C))<1 or f(s∩(B∪C))<1.

So it is sufficient to independently separate the biconnected components. These three reductions can be combined recursively to yield separation sub-problems that are significantly smaller than the original support hypergraph. For typical geometric instances with n=[V], one usually obtains reduced separation problems with at most 0.35n vertices, often much smaller. Since the subsets S⊂V identified as violations are subsets of these individual reduced separation sub-problems, it is not surprising that the violated subtours S discovered tend to have cardinality at most 0.35n, and usually much smaller.

Once the flow-based separator has discovered some violated subtour S, conventional GeoSteiner software performs “constraint strengthening” by recursively applying the reductions of Lemmas 4.1, 4.2 and 4.3 to the sub-hypergraph induced by S to further reduce the cardinality of the violation, possibly splitting S (via connected and biconnected components) into several much smaller (and vastly stronger) violated subtours.

If the original violation S has cardinality exceeding approximately 0.35n, then the EPR and CD metrics indicate that these cardinality reductions actually weaken the constraint—at least until the “weakest subtour” threshold has been passed. When starting with a violation S above this cardinality threshold, the metrics indicate that the cardinality of S must be increased in order to strengthen the resulting subtour inequality. Conventional versions of GeoSteiner software strengthen subtour violations only via reduction. In contrast, the test Geosteiner system described herein by the inventors also strengthen subtour violations via augmentation.

This is why conventional GeoSteiner software (versions 5.1 and earlier) is virtually incapable of identifying violated subtours S having large cardinality. In order for these versions of GeoSteiner to generate a violated subtour of large cardinality, the following events must happen simultaneously:

The initial reductions must be relatively ineffective, yielding a “reduced” separation sub-problem containing most of V.

The flow-separator must identify a violation S of large cardinality within this sub-problem.

The resulting S must mostly survive all reductions subsequently applied to “strengthen” subtours emerging from the flow-separator.

This confluence of events seems to be impossible for the geometric instances that typically arise within GeoSteiner software applications, but could potentially happen within certain more general classes of weighted hypergraphs.

### Improvements to GeoSteiner

We now describe the algorithmic improvements included in the test GeoSteiner system that are an improvement over GeoSteiner version 5.1. (Note GeoSteiner version 5.0 was described in the D. Juhl etl al. 2018 article. Version 5.1 contains little that would affect these computational results over those produced with version 5.0.)

### New Constraint Pool Size Management

In conventional GeoSteiner versions 5.1 and earlier, the constraint pool can grow unacceptably large. In the test GeoSteiner system, the inventors instituted a (user-adjustable) hard limit on the total number of non-zero coefficients for constraints in the constraint pool. This limit is now exceeded only when the set of binding constraints among all active branch-and-bound nodes must exceed this limit.

The constraint pool size management methods used here in this example included these operations: (1) Compute the number of rows and non-zeros needed by the set of constraints being added to the pool. (2) Compute minimum number of rows and non-zeros by which the current constraint pool must be reduced in order to make room for the new constraints. (3) Sort the existing constraints in the pool from largest number of non-zeros down to least number of non-zeros (ignoring constraints that are binding for any active branch-and-bound node). (4) Greedily remove dense constraints until the size limits have been reached (or all discardable constraints have been removed). (5) Add the new constraints to the pool. In a test example, these changes have almost no measurable impact upon the overall run time of GeoSteiner's branch-and-cut algorithm, but provide a much more reliable upper bound on the size of the constraint pool in the test GeoSteiner system.

### Method for Solving Over all Constraints in the Pool

Given an LP solution x, conventional GeoSteiner versions 5.1 and earlier scans the pool for all inequalities violated by x and adds all of these inequalities to the LP at once. This scan is repeated (after re-solving the updated LP) until an LP solution x is obtained that satisfies all inequalities in the constraint pool. (The code also deletes slack constraints inside this loop if the LP objective strictly improves.) This algorithm has the undesirable side-effect of filling up the LP tableaux with many very dense rows, including presumably many rows that are redundant. This effect is particularly acute on problems that require many optimize/separate iterations in order to satisfy all subtour inequalities at the root node, especially large random rectilinear instances.

To address this problem the inventors added to the test GeoSteiner system a “Sparse, Orthogonal, Stratified” (SOS) heuristic illustrated in example code provided in FIG. 15.

As shown in the code in FIG. 15, the sorting step causes the heuristic to favor sparse rows over dense rows. The “If statement chooses rows that are orthogonal to each other (no non-zero columns in common). Repeating this scan k times causes several “strata” of such constraints to be chosen during each such iteration over the pool. Thus the name Sparse, Orthogonal, Stratified.

This heuristic is reasonably effective at reducing the size and density of the Linear programs (LPs), especially on problems where many optimize/separate iterations are required. It is not totally effective, however. On very large, long-running problems we find that the LP can still be substantially reduced in size by starting over with the initial set of constraints (together with the current node's branching constraints) and re-running the SOS heuristic until all constraints in the pool are satisfied. This “restart” operation is computationally quite costly, however. Exploiting such “restarts” algorithmically requires some policy to decide when to invoke such a “restart” operation so that the benefit of sparser LPs obtained usually outweighs the cost of restart.

Although reasonably effective at keeping the LP smaller on very large problems, smaller problems generally experience a slight increase in solution time because of having to execute more “SOS” passes over the constraint pool before achieving an x that satisfies all constraints in the pool. We accept this small penalty in exchange for smaller LPs and better performance on large problems. We do not provide any detailed before/after execution data regarding this code change.

### Complementary Subtours

To exploit the greater “predicted” strength of large cardinality subtours, we tried the following operation. Whenever some subtour S gets added to the constraint pool, also add the complementary subtour V−S to the constraint pool. When |S| is small, |V−S| will be large. Although subtour V−S might not be violated by the present LP solution x, it might become violated by future LP solutions x′, at which time the next scan of the constraint pool will add it to the LP.

Such “complementary” subtours do in fact get pulled into the problem occasionally (5-25% of all SOS pool scans contain one or more such complementary subtours in tests). But these provided no measurable impact on solution times. Although these are subtours of large cardinality, they do not seem to be the “correct” large cardinality subtours for the instance.

### Constraint Strengthening Via Augmentation

We now describe a core algorithmic change in the test GeoSteiner system, yielding one of the most significant performance improvements in GeoSteiner since the 1998 D. Warme thesis. This new algorithm provides an additional method for strengthening subtour inequalities.

Let S⊂V be a violated subtour. GeoSteiner's existing method for strengthening S applies the various “reductions” to the support hypergraph induced by S, resulting in violations S′ such that |S′|≤|S|. The new strengthening algorithm explicitly targets subtours of large cardinality by “augmenting” S with additional vertices using methods that work by conceptually running the existing reductions “in reverse.”

### Single Vertex Augmentation

The first of these methods reverses the “iterative vertex removal” reduction of Lemma 4.1.

Theorem 5.1 (Single vertex augmentation) Let S⊂V, tϵV−S and S′=S∪{t}. If x(S)>|S|−1 and x(S:{t})≥1, then x(S′)>|S′|−1.

### Proof:

$$\begin{matrix}x ( {S}^{′} ) = x ( S ⋃ \{ t \} ) \\ = x ( S ) + x ( S : \{ t \} ) \\ \geq x ( S ) + 1 \\ > ( \vert S \vert - 1 ) + 1 \\ = \vert S \vert \\ = \vert {S}^{′} \vert - 1\end{matrix}$$

This provides the conditions under which a violated subtour S can be augmented with vertex t to obtain a violated inequality S′ of larger cardinality. This augmentation step is iterated greedily until no further valid augmentations exist. The algorithm maintains a heap containing the set F of “frontier” vertices:

F={vϵV−S:x(S:{v})>0}.

The heap is ordered to place vertex v having the largest x(S:{v}) at the top of the heap. The algorithm contains two additional arrays, vweight and vindex (indexed by vertex vϵV) that satisfy the following invariants:

$$vweight [ v ] = \{ \begin{matrix}x ( S : \{ v \} ) , & if v ∈ F ; \\ 0 , & otherwise\end{matrix} \\ Let v ∈ V and j = vindex [ v ] . Then \\ v ∈ S ⟹ j = - 2 ; \\ v ∈ F ⟹ heap [ j ] = v ; \\ Otherwise , j = - 1.$$

The greedy algorithm is presented in example code in FIG. 16. Note that the greedy augmentation algorithm in FIG. 16 augments S with vϵV such that x(S:{v})≤1, so long as the violation does not completely disappear. If we assume that the algorithm stops instead of employing any such “violation reducing” augmentation, we can argue that the algorithm always yields the same result S, regardless of the order in which the augmentations are executed. Under these conditions we note that all changes to the heap keys vweight[v] cause the keys to increase monotonically. For all vϵF, once vweight[v]≥1, this condition on v never becomes false and the augmentation by v will eventually happen. There is no way to “miss” the opportunity for any augmentation, regardless of the order in which the augmentations are performed. Thus the purely greedy algorithm always yields the same resulting S (at least until any “violation reducing” augmentations are made). For each valid sequence of “violation reducing” augmentations, the resulting S is the same regardless of the order in which the other augmentations are performed. One implementation in an example test GeoSteiner system not intended to be limiting is the strictly greedy algorithm presented here—it makes no attempt to optimize the sequence of such “violation reducing” augmentations.

### Augmentation by Complementary Connected Components

The next method is analogous to reversing the “connected components” reduction of Lemma 4.3.

We first prove a lemma that provides an alternate way of writing subtour inequalities.
Lemma 5.2 (Alternate form of subtour inequalities) Let xϵR^{m} such that x(V)=|V|−1, S⊂V such that |S|≥2 and H=V−S. Then x(S)≤|S|−1⇔x(H)+x(H:V−H)≥|H|. (5.1)

$$Proof : We have x ( V ) = \vert V \vert - 1. \\ \begin{matrix}x ( V ) = x ( S ) + x ( S : H ) + x ( H ) \\ = \vert V \vert - 1 \\ = ( \vert S \vert - 1 ) + 1 + ( \vert H \vert - 1 )\end{matrix} . \\ Subtracting inequality x ( s ) \leq \vert S \vert - 1 from this yields x ( S : H ) + x ( H ) \geq \vert H \vert , \\ which is equivalent to x ( H ) + x ( H : V - H ) \geq \vert H \vert .$$

We call (5.1) the “hole inequality for H,” or the the “anti-subtour inequality for H.” The hole inequality for H places a lower bound on the total edge material within H and crossing out of H. In contrast, the subtour inequality for H places an upper bound on the total edge material within H. See the example code in FIG. 17 illustrating a subroutine for a heap initiation, heap.init (V, S, x).

Theorem 5.3 (Augmentation via complementary connected components) Let H=(V, E) be a hypergraph, xϵR^{|E|} such that

$$x ( V ) = \vert V \} - 1 , \qquad ( 5.2 )$$

and S⊂V, such that |S|≥2 and

$$x ( S ) > \vert S \vert - 1.$$

Let K̅ be the support subhyper graph of H induced by V−S. Let (H₁, E₁), (H₂, E₂), . . . , (Hₖ, Eₖ) be the connected components of K̅, as shown in FIG. 11A. Then at least one of the Hᵢ(1≤i≤k) is a violated hole inequality. Proof: Assume that all hole inequalities Hᵢ are satisfied, i.e.,

$$x ( {H}_{i} ) + x ( {H}_{i} : V - {H}_{i} ) \geq \vert {H}_{i} \vert for all 1 \leq i \leq k . \qquad ( 5.3 )$$

Because the (Hᵢ, Eᵢ) are connected components of K̅, there is no edge eϵĒ crossing the cut between any pair Hᵢ, Hⱼ, i≠j. All edges crossing the cut (Hᵢ: V−Hᵢ) must therefore cross only cut (S: Hᵢ). Subtracting the hole inequalities (5.3) from Equation (5.2) yields:

$$\begin{matrix}x ( V ) - ( {\sum }_{i = 1}^{k} x ( {H}_{i} ) + {\sum }_{i = 1}^{k} x ( {H}_{i} : V - {H}_{i} ) ) \leq \vert V \vert - 1 - {\sum }_{i = 1}^{k} \vert {H}_{i} \vert ⟹ x ( V ) - ( {\sum }_{i = 1}^{k} x ( {H}_{i} ) + {\sum }_{i = 1}^{k} x ( {H}_{i} : S ) ) \leq \\ \vert V \vert - 1 - {\sum }_{i = 1}^{k} \vert {H}_{i} \vert \\ ⟹ x ( S ) \leq \vert S \vert - 1\end{matrix} ,$$

which contradicts the given condition x(S)>|S|−1. The assumption that all the hole inequalities Hᵢ are satisfied must therefore be false, so at least one of the hole inequalities Hᵢ must be violated by x.

Let H and x be as in Theorem 5.3, let/be the support hypergraph of H, and let (V₁,E₁), (V₂,E₂), . . . , (Vₖ,Eₖ) be the connected components of I. As noted previously, for each 1≤i≤k it suffices to independently apply the subtour separation oracle within (Vᵢ,Eᵢ). Let S⊆Vᵢ be such a violated subtour, and consider strengthening of S via Theorem 5.3. A direct application of Theorem 5.3 considers the sub-hypergraph J of I induced by V−S, and the corresponding set K of all connected components of J. For all 1≤j≤k, j≠i one finds that (Vⱼ,Eⱼ) is a member of K. Thus, each of these Vⱼ get reconsidered as potentially violated hole inequalities every time a new violated subtour in Vᵢ is discovered and strengthened via Theorem 5.3. This is a wasteful repetition of computational effort. A person of usual skill in the art will notice that it suffices to instead consider the sub-hypergraph L of (Vᵢ,Eᵢ) induced by Vᵢ−S, and the corresponding set M of all connected components of L. Although this loses the guarantee of Theorem 5.3 (that at least one of these connected components represents a violated hole inequality), this guarantee is recovered over the union of independently separating and strengthening each (Vᵢ,Eᵢ), 1≤i≤k. This eliminates all such duplication of effort during strengthening via Lemma 5.3.

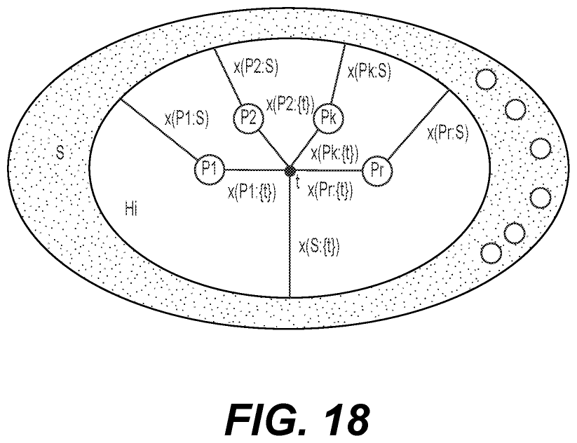

FIG. 18 shows an example illustration of augmentation via complementary biconnected components having a violated hole inequality according to an embodiment. See FIG. 18 shows connected component Hᵢ of V−S (Proof of Theorem 5.4).

Definition: A hypergraph is biconnected if it is connected, and remains so after the removal of any single vertex.

Definition: An articulation vertex t is a vertex of a connected graph whose removal splits the graph into two or more connected components. In a connected graph, it is the articulation vertices that form the boundaries between its biconnected components.

Theorem 5.4 (Augmentation via complementary biconnected components) Let H=(V, E) be a hypergraph, xϵR^{|E|} such that

$$x ( V ) = \vert V \vert - 1 ,$$

and S⊂V, such that |S|≥2 and

$$x ( S ) > \vert S \vert - 1 , \\ and \\ x ( S : \{ u \} ) < 1 for all u ∈ V - S .$$

Let K be the support subhypergraph of H induced by V−S. Let (Hᵢ, Eᵢ) be a connected component of K (as shown in FIG. 11A) such that Hᵢ is a violated hole inequality:

$$x ( {H}_{i} ) + x ( {H}_{i} : V - {H}_{i} ) < \vert {H}_{i} \vert \qquad ( 5.6 )$$

(By Theorem 5.3, at least one such connected component must exist.)

Let (U̅₁̅, E̅₁̅), (U̅₂̅, E̅₂̅), . . . , (U̅ₘ̅, E̅ₘ̅) be the biconnected components of (Hᵢ, Eᵢ).

Then at least one of the hole inequalities

$$x ( \overline{{U}_{j}} ) + x ( \overline{{U}_{j}} : V - \overline{{U}_{j}} ) \geq \vert \overline{{U}_{j}} \vert for all 1 \leq j \leq m \qquad ( 5.7 )$$

must be violated.

Proof: If (Hᵢ, Eᵢ) has no articulation points, then it is biconnected and (Hᵢ, Eᵢ) is the only biconnected component. As given, Hᵢ is already a violated hole inequality.

Otherwise, (Hᵢ, Eᵢ) has at least one articulation vertex. Let t be any articulation vertex of (Hᵢ, Eᵢ). Let r≥2 be the number of connected components that (Hᵢ, Eᵢ) splits into upon removal of t, and let Pₖ be the vertex set of the k-th connected component, for 1≤k≤r. Let Qₖ=Pₖ ∪{t} for 1≤k≤r. Assume that all the hole inequalities Qₖ are satisfied, e.g. x(Qₖ)+x(Qₖ:V−Qₖ)≥|Qₖ| for all 1≤ k≤r.

We obtain a contradiction as follows. Note that no edge crosses from Pᵢ to Pⱼ for any 1≤i<j≤r. Any edge crossing cut (Pₖ:V−Pₖ) can only cross (Pₖ:{t}), (Pₖ:S), or both. The situation is illustrated in FIG. 18. Define

$$θ = ( {\sum }_{k = 1}^{r} x ( {P}_{k} ) + x ( {P}_{k} : S ) + x ( {P}_{k} : \{ t \} ) - \vert {P}_{k} \vert ) + x ( S : \{ t \} ) \\ Then \\ x ( {H}_{i} ) + x ( {H}_{i} : V - {H}_{i} ) < \vert {H}_{i} \vert ⇔ θ < 0.$$

We now sum all of the satisfied hole inequalities Qₖ:

$$\begin{matrix}{\sum }_{k = 1}^{r} x ( {Q}_{k} ) + x ( {Q}_{k} : V - {Q}_{k} ) \geq {\sum }_{k = 1}^{r} \vert {Q}_{k} \vert ⟹ {\sum }_{k = 1}^{r} x ( {Q}_{k} ) + x ( {Q}_{k} : S ) \geq {\sum }_{k = 1}^{r} \vert {Q}_{k} \vert \\ ⟹ {\sum }_{k = 1}^{r} x ( {P}_{k} ) + x ( {P}_{k} : S ) + x ( {P}_{k} : \{ t \} ) + \\ x ( S : \{ t \} ) \geq r + {\sum }_{k = 1}^{r} \vert {P}_{k} \vert \\ ⟹ {\sum }_{k = 1}^{r} x ( {P}_{k} ) + x ( {P}_{k} : S ) + x ( {P}_{k} : \{ t \} ) + \\ x ( S : \{ t \} ) - \vert {P}_{k} \vert \geq r \\ ⟹ rx ( S : \{ t \} ) + {\sum }_{k = 1}^{r} x ( {P}_{k} ) + x ( {P}_{k} : S ) + \\ x ( {P}_{k} : \{ t \} ) - \vert {P}_{k} \vert \geq r \\ ⟹ ( r - 1 ) x ( S : \{ t \} ) + θ \geq r \\ ⟹ θ \geq 1 + ( r - 1 ) ( 1 - x ( S : \{ t \} ) ) \\ ⟹ θ - 1 \geq ( r - 1 ) ( 1 - x ( S : \{ t \} ) )\end{matrix}$$

Because θ<0 and r≥2, this implies that x(S:{t})>1. We are given that x(s:{u})<1 for all uϵV−S. This is contradicted for u=t. There must therefore be at least one Qₖ(1≤k≤r) that is a violated hole inequality.
We did not specify which articulation point t to choose, so the above argument can be repeated for every articulation point t of (Hᵢ, Eᵢ).
These articulation points partition (Hᵢ, Eᵢ) into biconnected components (U̅₁̅, E̅₁̅), (U̅₂̅, E̅₂̅), . . . , (U̅ₘ̅, E̅ₘ̅).
At least one of the Ūⱼ (1≤j≤m) must therefore be a violated hole inequality.

### General Augmentation

The next method is an augmentation by some general subset U of the remaining vertices, a theorem stated without proof:

### Theorem 5.5 (General Augmentation)

Let H=(V, E) be a hypergraph, xϵR^{|E|} such that x(V)=|V|−1, S⊂V such that |S|≥2 and x(S)>|S|−1, and U⊆V−S such that

$$x ( U ) + x ( S : U ) \geq \vert U \vert . \\ Then \\ x ( S ⋂ U ) > \vert S ⋂ U \vert - 1.$$

One skilled in the start can conceive many methods for embodying the general augmentation method. In one embodiment, subsets U of small cardinality are enumerated, looking for U having the correct properties. In other embodiments, subsets U having this property are discovered as the vertex set of connected or biconnected components being processed. Numerous other embodiments are possible.

One skilled in the art should be able to adapt and extend the above proofs for the corresponding cases of the Steiner tree in hypergraph problem. Our improved constraint strengthening implementation within GeoSteiner processes every violated subtour S generated by the deterministic flow separation algorithm described in 1998 D. Warme thesis. It first applies the existing “strengthening by reduction” methods. It then applies the new “strengthening by augmentation” methods described herein. For given violated subtour S, it first applies the greedy augmentation algorithm, yielding an augmented violation S′. It then computes the connected and biconnected components of V−S′. It then tests each biconnected component Uᵢ⊂V, generating each violated hole inequality. (Various embodiments might apply or repeat these steps in various sequences.) The equivalent subtour V−Uᵢ is both violated, and of large cardinality—which the EPR an CD strength metrics both predict to be very strong. See, FIG. 18 (Proof of Theorem 5.4.). Because they are violated by the current LP solution x, they are also very pertinent to the problem being solved (unlike complementary subtours), which are almost never violated by the current LP solution x—only “accidentally” by future LP solutions x′).

This enhancement is so computationally successful that every problem in our test set now rapidly converges all of the subtour constraints at the root node. At most 150 optimize/separate iterations were required for each of these problems. Because so few iterations are required, there is little opportunity for useless or redundant constraints to accumulate within the LP. Since the LP contains generally stronger constraints (which are more sparse), the LP A matrix remains much smaller, the LPs solve much more quickly, and the solution vector x is much cleaner numerically. Cleaner x cause the reductions to remain much more effective, decreasing the size of instances presented to expensive flow separator. These effects greatly decrease the overall cost of the separation algorithm. It is significant that simply adding some new, stronger constraints to the mix of violated subtours generated produces so many virtuous feedback cycles within the branch-and-cut algorithm as a whole.

The new GeoSteiner package (modified to perform augmentation) used to obtain computational test results reported herein did not use the insight described above to avoid the duplication of effort created by a direct application of Theorem 5.3 (augmentation via complementary connected components) when the LP solution x denotes a hypergraph having k connected components, where k>1. The implementation instead used hash tables and other data structures to eliminate these duplicates dynamically, each time they were rediscovered.

The net result of this new subtour-strengthening-by-augmentation method is that convergence of the subtour relaxation at the root node is no longer a problem on any of the many test instances in our test GeoSteiner system. (Convergence of local cuts could potentially be an issue in limited cases, but this is rare in practice.) Branching is the major remaining issue that can cause problems to take so long that we choose in one example to abandon the computation rather than wait for all necessary nodes to be enumerated.

### Choosing Branch Variables Via Pseudo Costs

The branch variable selection algorithm used (by default) in GeoSteiner versions 5.1 and earlier is useful on problems that require at most a few dozen branch-and-bound nodes, but becomes hopelessly inefficient when much more branching is required. Let F be the list of fractional variables, which the algorithm places into a heuristically sorted order. It then performs “strong branching” (actually solving the LP for both branches) on the first k members of F, where k=2└ log₂([F])┘. It chooses the variable whose minimum “down branch” versus “up branch” objectives is maximized. When solving the “down branch” and “up branch” LPs, the code also invokes the primal upper bound heuristic on each resulting LP solution. (This primal heuristic turns out to be significantly more costly than solving the LP for each branch, especially on very large problems.) The default algorithm stops immediately on any variable for which one or more of the branches yields an infeasible LP or a cutoff. Although this causes the variable to be fixed without branching, the same variable selection process usually starts over from scratch, testing the same variables in the same order as before. This algorithm wastes significant amounts of CPU time, e.g., on random rectilinear instances above 4000 points, becoming completely intolerable at 15,000 to 40,000 points.

To alleviate this inefficiency, we implemented a new branch variable selection algorithm in the test GeoSteiner system that uses pseudo costs to choose branch variables. Let x be an LP solution, z=c x be its optimal objective value, and eϵE such that xₑ is fractional (0<xₑ<1). We define

$${c}_{e}^{0} = \frac{{z}_{e}^{0} - z}{{x}_{e}} , and \qquad ( 5.8 )$$

$${c}_{e}^{1} = \frac{{z}_{e}^{1} - z}{1 - {x}_{e}} , \qquad ( 5.9 )$$

where zₑ⁰ is the LP objective value with branch condition xₑ=0 imposed, and zₑ^{J} the LP objective value with branch condition xₑ=1 imposed. We call cₑ⁰ the “downward pseudo cost of xₑ,” and cₑ¹ the “upward pseudo cost of xₑ.” Using pseudo costs, a good branch variable xₑ can be selected using

$$e = arg {max}_{e ∈ \tilde{E}} ( min ( {c}_{e}^{0} {x}_{e} , {c}_{e}^{1} ( 1 - {x}_{e} ) ) ) , \qquad ( 5.1 )$$

where \check{E}={eϵE:xₑ is fractional}. If the pseudo costs are always accurate, this is analogous to “full” strong branching at each node.

Calculating pseudo costs for a single fractional variable is mildly expensive, requiring the solution of two LPs. Calculating them for all fractional variables assures accuracy but is very expensive.

It has been observed that pseudo costs generally remain fairly stable during the branch-and-bound process. This property can be exploited to choose very good branch variables at reasonably low amortized cost.

In one example, we tried a simple method having a single global array of pseudo costs (indexed by eϵE, initially undefined), where pseudo costs were calculated as needed and cached in this array. At the root node, this means that pseudo costs are calculated for all fractional variables. This method performs very well on problems requiring a few thousand nodes or less, but gets progressively worse with larger branch-and-bound trees, because cached pseudo costs diverge from their true values, which are node-specific.
In our improved pseudo cost method:
Pseudo costs are stored for each branch-and-bound node,
Child nodes inherit pseudo costs from their parents, and
Pseudo costs are occasionally re-calculated so that they remain more accurate during branch-and-bound.

Unfortunately, we don't know which pseudo costs change from parent to child node (unless we re-calculate them all). We instead use a heuristic to re-calculate “some” pseudo costs at each node, seeking to balance pseudo cost accuracy (and branch variable quality) versus computational cost.

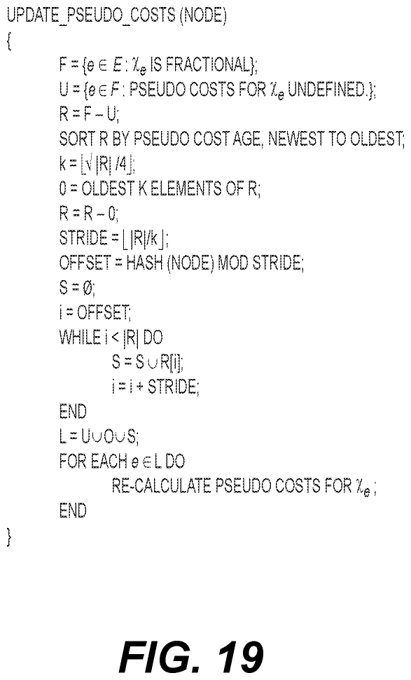

Our heuristic is presented in example code shown in FIG. 19. The set L⊆E of edges for which pseudo costs are calculated consists of
U: edges having undefined pseudo costs;
O: the k oldest pseudo costs; and
S: a “stratified random sample” of remaining fractional variables. The starting offset for this sample is not actually random, but calculated from a hash of all branch conditions imposed upon this node up to the root node.

The primal heuristic is invoked only on the children of the branch variable finally selected.

In this example a method of choosing branch variables is used which generally performs better than conventional GeoSteiner software current default branch variable selection method. Because it evaluates pseudo costs for every fractional variable at the root node, this new method is generally a bit slower than GeoSteiner's default method in some cases on problems having small branch-and-bound trees. It does, however, perform substantially better on problems having medium to large branch-and-bound trees.

### Computational Results

Results for the previous version of GeoSteiner software are taken verbatim from D. Juhl et. al. 2018. We note that those results “Original” in FIGS. 21A-21F were obtained on twelve paravirtualized guests sharing a HP ProLiant BL685c generation 7 server, with 256 GB of memory and four AMD Opteron 6380 CPUs, each having sixteen cores running at a base clock rate of 2.5 GHz. The twelve guests were running the 64-bit version of Debian 7.4.0 while the host was running OpenSuse 12.3. The source code was compiled with GNU C 4.4.508 for Debian, with optimization flag —O2.

The new computations “New” in FIGS. 21A-21F were performed on a computer built with the following components:
CPU: AMD Ryzen Threadripper 2950X (16 cores, base clock 3.5 GHz max boost clock 4.4 GHz, 40 MB combined cache)
Memory: 128 GB DDR4 3200 MHz with ECC
Motherboard: Asus ROG Strix X399-E Gaming

The operating system is the 64-bit version of CentOS 7.7.1908. The source code was compiled using Red Hat GCC 4.8.5-39 with the optimization flag —O2.

CPLEX version 12.5.1 was used as the LP solver in both experimental setups. Because GeoSteiner implements its own native branch-and-cut framework, it uses CPLEX only as an LP solver, and generally uses default settings for all CPLEX LP solver algorithmic parameters. The FST generation and pruning code has not changed, but the execution times for these steps have changed because they were re-run on the new, faster machine. Since only the concatenation code has changed, it is the change in concatenation time that is of most interest in these results.

Note the following regarding the large randomly generated instances:
1. In D. Juhl et al. 2018 article, not all instances solved at 50,000 points (8 out of 15) and 100,000 points (3 out of 15);
2. Because of the lengthy computation times we have only attempted solution of instance 1 (out of 15) for Euclidean instances of size 250,000, 500,000 and 1,000,000 points, and rectilinear instances at sizes 15,000 to 40,000 points. (This is why the standard deviations are zero.)

Note that every computation attempted on these large random instances has resulted in an optimal solution. This represents roughly an order of magnitude improvement in the size of random instances solvable in both the Euclidean and rectilinear metrics.

### Discussion

We now discuss various observations and ramifications regarding the above.

### Why Large Subtours are so Effective

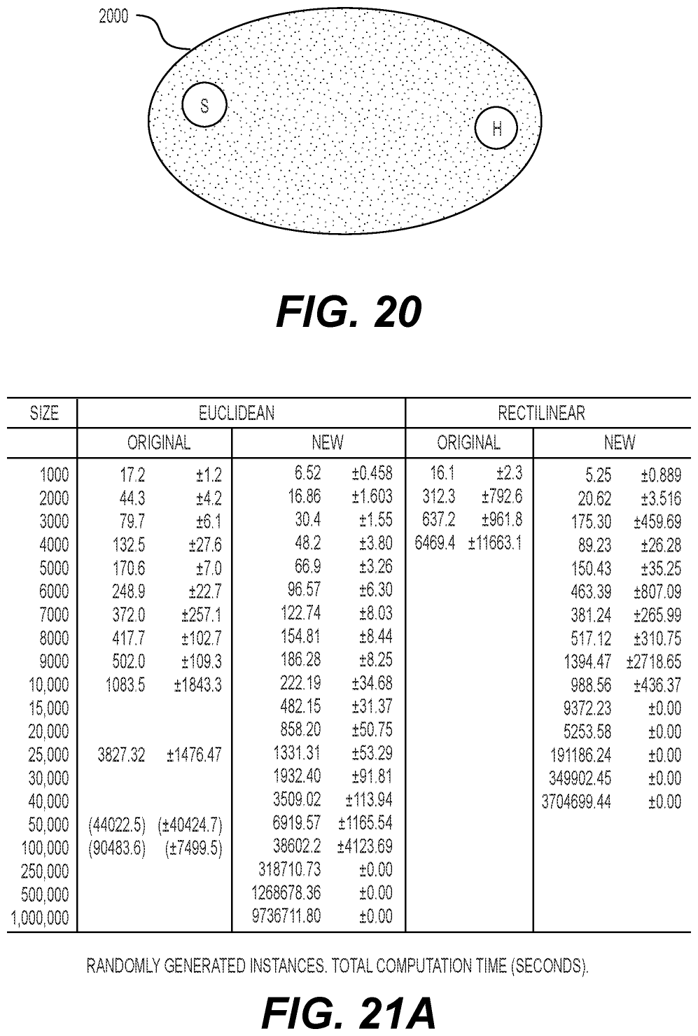

The stunning algorithmic success achieved when using subtours of both small and large cardinality begs an intuitive explanation. Consider the situation graphically illustrated in FIG. 20, depicting an instance 2000 having a violated subtour S of small cardinality and a violated hole H of small cardinality (equivalent to subtour V−H of large cardinality). Subset S contains too much edge material, while subset H (together with its corresponding cut) contains a deficit of edge material. Assume for convenience that both violations have relatively large magnitude. Generating subtours of small cardinality “pushes” edge material out of regions that have excess. A useful analogy is pushing clay away from areas having too much clay while fabricating a bowl. Each time some region is identified as having excess, a new constraint is generated requiring the excess material to go elsewhere. Suppose we restrict to using only such “push” operations. Because H is quite a long distance away from the original S, and because the objective function offers many intervening “topographical ridges and valleys” for the pushed material to enter, it is easy to see that it might take a large number of such “pushes” before enough edge material finally migrates sufficiently far away from S (and intervening objective function ridges and valleys) to finally arrive at H and start satisfying its deficit. As material is pushed outward, it spreads over a wider, more diffuse area, and new violations are likely to consist of larger, weaker subtours that continue to disperse material over wider areas, further delaying the arrival of sufficient material to satisfy the deficit at H.

Now consider the case where one simultaneously generates both subtour S and hole H (equivalent to large cardinality subtour V−H). The “push” from S together with the “pull” from H immediately fixes both the excess at S and the deficit at H. Furthermore, because of the “conservation of edge material” provided by equation (3.2), the excess at S rather directly “feeds” the deficit at H. The rest of the problem stands cleanly on its own, competing for the difference between S's excess and H's deficit.

This is an intuitive explanation for the convergence efficiency achieved when combining the local “push” of small cardinality subtours with the local “pull” of large cardinality subtours. Both of these constraints are very strong and greatly reduce the remaining feasible space, while avoiding unnecessary interactions with the objective function “ridges and valleys” between them (whose correction generally induce subtours that are weaker and more dense).

### Effectiveness of Separation Oracles

We have much computational experience indicating that the particular choice of which violated inequalities are generated can cause performance to vary by many orders of magnitude. Consider the landmark result of Grötschel, Lovász and Schrijver, which proved that so long as: (1) the inequality class is finite, and (2) the separation oracle is guaranteed to find at least one violated inequality if any violations exist, then the ellipsoid algorithm terminates using O(d² log(R/r)) calls to the separation oracle, where d is the dimensionality of the space, R is the radius of a ball completely containing the polytope P, and r is the radius of a ball completely contained within the polytope P. See, M. Grotschel, L. Lovasz, and A. Schrijver, The ellipsoid method and its consequences in combinatorial optimization, Combinatorica, 1(2):169-197, 1981.

By comparison, very little is known regarding bounds on the number of iterations of the analogous loop wherein the simplex algorithm is used to optimize over the current set of constraints. The sequence of successive LP solutions x have no relationship whatsoever to the center points of the successive ellipsoids in the ellipsoid algorithm, nor is there any corresponding constant factor by which the volume of successive ellipsoids must decrease. No matter how similar the two algorithms might appear, nor how theoretically attractive the iteration bound for the ellipsoid algorithm may be, we know of no good upper bounds on the number of iterations that might be required by the “more practically used” loop that separates successive LP solutions.

Computational experience (including that described herein) clearly indicate that using a separation oracle that chooses “strong” violated inequalities over “weaker” violated inequalities can result in a huge reduction in the number of iterations needed to satisfy the entire class of inequalities. In contrast, a separation oracle that chooses inequalities unwisely (failing to find “strong” violated inequalities when they exist) can have devastating computational consequences, taking so long to converge in practice that computations are either abandoned, or some “tailing off” decision is made to invoke branching.

Note that proving some class of inequalities to be facet-defining offers no assurance of rapid convergence—the metrics described herein demonstrate that strength varies widely within such facet classes, even for polytopes having extremely high levels of symmetry. The attitude that, “any violated inequality in such a class is good enough,” should be actively discarded when designing separation algorithms for real computations.

In the past, “tuning” a separation algorithm so that it converges rapidly has usually been at best an art, and more often a process of “trial and horror.” We propose that strength metrics (such as EPR and CD) should guide the design of separation and constraint strengthening algorithms, resulting in a more principled, empirically based approach to obtaining high-performance, rapidly converging separation algorithms.

### Common Algorithmic Patterns Yielding Bias

There is a pattern here that is common for almost any algorithm that separates a combinatorially large class of inequalities:
The underlying separation algorithm f(x) is computationally costly.
Mitigate this by first applying reductions.
Apply f(x) to reduced sub-problems, which are smaller.
Resulting violated inequalities are clustered within one portion of the inequality class.

These are commonly occurring themes in many combinatorial optimization problems. This pattern can result in a form of “algorithmic bias” that systematically avoids large portions of the inequality space. (This more technical form of algorithmic bias should not be confused with the “social” type of algorithmic bias being heavily discussed within the machine learning community.) The present example of STHGP subtours shows that (at least for some problems), this can bias the algorithm away from very strong or even the strongest inequalities in the class. Correcting this bias yields enormous performance gains in GeoSteiner.

This provides yet another incentive for calculating such strength metrics for a particular polytope/inequality class—if this algorithmic bias systematically avoids regions of the inequality space containing very strong inequalities, then one can devise methods that specifically target these strong inequalities that would otherwise be missed.

### Future Research and Further Applications

### Problem-Specific Dynamics

In STHGP, we find that intentionally targeting all of the strong inequalities simultaneously yields a stunning improvement in the convergence rate over the class of subtours. This rapid convergence is associated with an intuitive and very problem-specific dynamic (as described above) that does not appear when the strong constraints are only partially covered (e.g., only subtours of small cardinality). We conjecture that:
When all regions containing strong inequalities are intentionally, effectively and simultaneously covered by “metric informed” separation algorithms for other problems, similar speedups will arise.
Problem-specific dynamics associated with this speedup will appear.
Suppose an inequality class has k≥2 disjoint regions containing strong inequalities. Simultaneously covering a larger superset of these k regions yields significant, measurable improvement in the convergence rate.
New problem-specific dynamics may arise with each larger superset of the k regions covered.

### Iteration Bounds

Earlier we recalled the excellent iteration bound afforded by the ellipsoid algorithm, while decrying how little is known about iteration bounds associated with the “more practical” simplex/separate loop. For a given polytope and class of inequalities, consider if use combinatorial and/or geometric properties similar to the EPR and CD metrics to obtain better upper bounds on the number of iterations needed by the “more practical” simplex/separate loop These bounds might be a function of the “strength” of inequalities already generated (as estimated by the metric). For example, the iteration upper bound gets smaller as more very strong inequalities from the class are generated. Perhaps we can use shrinking feasible volume and/or decreasing feasible extreme points in lieu of decreasing ellipsoid volume to obtain an interesting bound. Some traction may also be obtained by assuming some objective c and considering the cone of optimal directions around c associated with said polytope and/or the inequality class.

### CONCLUSION

For any problem having exponential time complexity, increasing the size of instances that can be practically solved by a factor 2 is dramatic progress. A factor of 10 improvement, however, is truly stunning. This improvement was not obtained by introducing any new class of cuts, but by improving the convergence rate over an existing, exponentially large class of cuts.

The code changes that yielded this performance gain were motivated by the property of STHGP(n) (as predicted by the EPR and CD metrics) that subtours of large cardinality are even stronger than subtours of small cardinality. This property of STHGP(n) was neither known nor suspected until clearly revealed by these metrics. The accuracy of these metrics as strong predictors of actual computational strength is now unambiguously confirmed, as is their usefulness for obtaining rapidly converging separation algorithms in an empirical, principled manner.

### Further Applications

Electronic design system 100 including graph engine 102 (and any of its components 105, 110, 115, 120, 125) or modeling tool 130 can be used in a number of applications. Terminal data sets 107 can be input representing terminals for data in a number of different applications and models. Similarly, electronic design system 101 including hypergraph engine 103 (and any of its components 120, 125) or modeling tool 130 can be used in a number of applications. Edge-weighted hypergraph data 117 can be input representing terminals for data in a number of different applications and models.

### Design and Layout of VLSI Circuits

Signals on electronic chips are connected by wires, usually fabricated with metal, such as aluminum. The velocity of these signals is upper-bounded by the speed of light, and further restricted by RLC and transmission line effects. Processing speed is maximized by minimizing signal propagation delay, for which wire length is a reasonably good proxy. Fabrication issues make it convenient to route these wires in layers that alternate between those having horizontal wires, and those having vertical wires, with vias providing connectivity between layers. Thus, the rectilinear Steiner tree is a good model for minimizing the length of a single circuit net. These can be computed by first generating the candidate rectilinear Full Steiner Trees (FSTs), and then concatenating the FSTs by reduction to the Minimum Spanning Tree (MST) in hypergraph problem, whose formulation as an integer program is in the context of this patent. Since wires must often be confined to well-defined routing channels, the obstacle-avoiding rectilinear Steiner tree provides a good model for obtaining short interconnects in this case. One first generates the obstacle-avoiding rectilinear Full Steiner Trees (FSTs), and then concatenates these FSTs by reduction to the Steiner tree in hypergraph problem, whose “undirected” formulation as an integer program is also in the scope of this patent. When trees obtained by these or other methods are infeasible (because of routing congestion, obstacle violation or other issues), Steiner trees (for example, that ignore these factors) can be used as initial solutions that other methods modify to obtain a feasible tree, or as “hints” or “suggestions” for manual route editing.

In one example, terminal data having 2000-8000 points can be used on semiconductor chip layouts including portions of semiconductor regions on the same or different planes or having interconnections between components on a semiconductor die or between dies within a package.

### Planning of Network Capital Expansion

Consider natural gas utility companies, that in the United States are not legally obligated to serve every customer who might want natural gas supply lines installed to their premises. Given: (1) an existing network of physical pipes: (2) cost, capacity and route of expansion pipes that could be built: (3) estimated gas demands and revenues for each potential customer site; and (4) a set of capital expenditure budgets b₁<b₂<b₃< . . . <bₖ. For each budget bⱼ, compute the feasible set of expansion pipes costing at most bⱼ to install that captures the maximum revenue from customer sites so connected. This can be modeled as a prize-collecting Steiner tree in graphs, which can be expressed using the “undirected” formulation for the Steiner tree in hypergraph formulation discussed in this patent. The existing network of physical pipes can be modeled as a single terminal vertex (the only terminal in the problem instance). Physical junction locations and potential customer sites become Steiner vertices, and the y variable associated with each potential customer site has an objective coefficient equal to the negative of the revenue “prize” associated with connecting said customer. Finally, a single budget constraint a x≤bⱼ, where aᵢ is the cost needed to install potential expansion pipe i. This formulation can easily be extended to model network flow capacities using additional variables to model flow of the gas commodity from the terminal to the demands at each selected customer site, as well as choosing between various capacity options for each potential expansion pipe. The minimum cost Steiner tree represents the maximum revenue that can be captured using a capital budget of bⱼ. By varying the budgeted amount bⱼ, one may obtain the Pareto frontier for this capital budgeting problem. Similar applications arise with wired and fiber-optic telecom networks, where the network provider might refuse to provide service to certain customers that might have to fall back to wireless or satellite-based connectivity.

### Quantum Computing

Although much present quantum computing research is based upon the notion of quantum entanglement, wherein the quantum state of two or more particles are coupled: the state of each particle cannot be expressed independently of the others. This results in what Einstein called “spooky action at a distance.” Any measurement of any of the particles causes instantaneous collapse of the quantum state in a manner that may be perfectly correlated between the particles. In theory, the instantaneous collapse does not depend upon the distance between the particles, seemingly in violation of the speed of light. (However, no information transfer violating the speed of light is possible using this effect.) There are other quantum effects, however, that are more local (e.g., tunneling) that could perhaps be harnessed for quantum computing. In such cases, it may become important to design good, short interconnection networks between the requisite qubits. Even when entanglement is used, distance is a factor since entangled particles are always generated together and then physically separated, which being limited by the speed of light takes time. All of the techniques described in this patent could be applicable to such applications.

### Microfluidic Devices

In some cases, the fluid channels must be kept short. Consider, e.g., cases where desired reaction products are short-lived—fluid velocity, reaction product decay and concentration requirements place bounds upon maximum fluid channel length. This is another application area where short network links become desirable, and the techniques described in this patent could be applicable.

### Further Embodiments and Example Implementations

Various embodiments of systems 100, 101 (including graph engine 102 and its components 110-125 and including hypergraph engine 103 and its components 120-125) and modeling tool 130 can be implemented on one or more computing devices. The computing devices may be at the same or different locations. A computing device can be any type of device having one or more processors and computer-readable memory. For example, a computing device can be a workstation, mobile device (e.g., a mobile phone, personal digital assistant, tablet or laptop), computer, server, computer cluster, server farm, game console, set-top box, kiosk, embedded device or system, or other device having at least one processor and computer-readable memory. In addition to at least one processor and memory, such a computing device may include software, firmware, hardware, or a combination thereof. Software may include one or more applications and an operating system. Hardware can include, but is not limited to, a processor, memory and user interface display or other input/output device.

Aspects of computing embodiments may also include networking configuration having clients and servers (including remote users on remote computing devices coupled to modeling tool 130 or graph engines 102, 103) over a network and may be implemented electronically using hardware, software modules, firmware, tangible computer readable or computer usable storage media having instructions stored thereon, or a combination thereof and may be implemented in one or more computer systems or other processing systems.

Embodiments are also directed to computer program products comprising software stored on any computer-usable medium. Such software, when executed in one or more data processing devices (such as a processor), causes a data processing device(s) to operate as described herein or, as noted above, allows for the synthesis and/or manufacture of electronic devices (e.g., ASICs, or processors) to perform embodiments described herein. Embodiments employ any computer-usable or -readable medium, and any computer-usable or -readable storage medium known now or in the future. Examples of computer-usable or computer-readable mediums include, but are not limited to, primary storage devices (e.g., any type of random access memory), secondary storage devices (e.g., hard drives, floppy disks, CD ROMS, ZIP disks, tapes, magnetic storage devices, optical storage devices, MEMS, nano-technological storage devices, etc.), and communication mediums (e.g., wired and wireless communications networks, local area networks, wide area networks, intranets, etc.). Computer-usable or computer-readable mediums can include any form of transitory (which include signals) or non-transitory media (which exclude signals). Non-transitory media comprise, by way of non-limiting example, the aforementioned physical storage devices (e.g., primary and secondary storage devices).

In accordance with the various embodiments described herein, one or more of the computer readable components and/or computer-implemented method features described herein can be loaded onto, and/or executed by, a programmable apparatus (e.g., comprising one or more processors. When executed, the computer readable components and/or computer-implemented method features described herein can cause the programmable apparatus to implement one or more of the various functions and/or operations exemplified in the referenced flow diagrams and/or block diagrams.

In the flow diagrams and/or block diagrams of the Drawings, the various blocks can represent one or more modules, segments, and/or portions of computer readable instructions for implemented one or more logical functions in accordance with the various embodiments described herein. Moreover, in one or more embodiments, one or more of the illustrated blocks can be implemented by special purpose hardware based systems.

As used herein, the term “or” is intended to be inclusive, rather than exclusive. Unless specified otherwise, “X employs A or B” is intended to mean any of the natural incisive permutations. That is, if X employs A: X employs B: or X employs both A and B, the “X employs A or B” is satisfied. Additionally, the articles “a” or “an” should generally be construed to mean, unless otherwise specified, “one or more” of the respective noun. As used herein, the terms “example” and/or “exemplary” are utilized to delineate one or more features as an example, instance, or illustration. The subject matter described herein is not limited by such examples. Additionally, any aspects, features, and/or designs described herein as an “example” or as “exemplary” are not necessarily intended to be construed as preferred or advantageous. Likewise, any aspects, features, and/or designs described herein as an “example” or as “exemplary” is not meant to preclude equivalent embodiments (e.g., features, structures, and/or methodologies) known to one of ordinary skill in the art.

Understanding that it is not possible to describe each and every conceivable combination of the various features (e.g., components, products, and/or methods) described herein, one of ordinary skill in the art can recognize that many further combinations and permutations of the various embodiments described herein are possible and envisaged. Furthermore, as used herein, the terms “includes,” “has,” “possesses,” and/or the like are intended to be inclusive in a manner similar to the term “comprising” as interpreted when employed as a transitional word in a claim.

Embodiments of the present invention have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The breadth and scope of the present invention should not be limited by any of the above-described exemplary embodiments.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

1. A computer-implemented method for graphical tree generation between terminal points, comprising:
receiving a terminal data set, wherein the terminal data set includes data identifying a number of terminal points;
generating, with at least one processor, an initial set of trees based on the terminal data set, wherein each tree couples two or more terminal points in the terminal data set;
concatenating, with at least one processor, the initial set of trees to obtain a culled subset of trees that meet or exceed concatenation criteria; and
outputting, with at least one processor, the culled subset of trees as a graph spanning the terminal points in the terminal data set,
wherein the concatenating includes augmenting one or more subtours (S) by adding one or more vertices to strengthen violated inequalities.

2. The method of claim 1, wherein the initial set of trees include full Steiner trees (S).

3. The method of claim 1, wherein the graph output comprises a Steiner minimum tree between the terminal points.

4. The method of claim 1, wherein the augmenting includes adding vertices to a subtour in a hypergraph formed from the initial set of trees.

5. The method of claim 1 wherein the augmenting includes performing a single vertex augmentation to a subtour.

6. The method of claim 1, wherein the augmenting includes performing a greedy augmentation of subtour inequalities by repeatedly performing single vertex augmentation to a subtour.

7. The method of claim 1, wherein the augmenting adds complementary connected components to a subtour.

8. The method of claim 1, wherein the augmenting adds complementary biconnected components to a subtour.

9. A computer-implemented system for graphical tree generation, comprising:
a storage device configured to store a terminal data set; and
a graph engine, implemented on at least one processor, configured to generate a graph spanning terminal points in the terminal data set based on an augmentation that adds one or more vertices to strengthen one or more violated subtour inequalities(S).

10. The system of claim 9, wherein the generated graph comprises a Steiner minimum tree between the terminal points.

11. The system of claim 9, wherein the graph engine is further configured to generate an initial set of trees based on the terminal data set wherein each tree couples two or more terminal points in the terminal data set, and concatenates the initial set of trees to obtain a culled subset of trees that meet or exceed concatenation criteria.

12. The system of claim 9, wherein the graph engine is further configured to perform a single vertex augmentation to a subtour.

13. The system of claim 9, wherein the graph engine is further configured to perform a greedy augmentation of subtour inequalities by repeatedly performing single vertex augmentation to a subtour.

14. The system of claim 9, wherein the graph engine is further configured to add complementary connected components to a subtour.

15. The system of claim 9, wherein the graph engine is further configured to add complementary biconnected components to a subtour.

16. The system of claim 11, wherein the initial set of trees comprise full Steiner trees.

17. The system of claim 16, wherein the graph engine includes:
a graph generator configured to generate an initial set of full Steiner trees (FSTs) based on the terminal data set, wherein each FST couples two or more terminal points in the terminal data set; and
a graph concatenator having an augmenter and configured to concatenate the initial set of FSTs to obtain a culled subset of FSTs that meet or exceed concatenation criteria and to output the culled subset of FSTs,
wherein the augmenter is configured to perform an augmentation of one or more vertices that strengthen a violated subtour inequality evaluated during the FST concatenation.

18. The system of claim 17, wherein the graph engine further includes a pruner coupled between the graph generator and graph concatenator.

19. The system of claim 17, wherein the augmenter is configured to perform an augmentation that includes adding vertices to a hypergraph.

20. The system of claim 17, wherein the augmenter is configured to perform a single vertex augmentation to a subtour.

21. The system of claim 17, wherein the augmenter is configured to perform a greedy augmentation of subtour inequalities by repeatedly performing single vertex augmentation to a subtour.

22. The system of claim 17, wherein the augmenter is configured to add complementary connected components to a subtour.

23. The system of claim 17, wherein the augmenter is configured to add complementary biconnected components to a subtour.

24. The system of claim 9, further comprising: a modeling tool configured to model a physical representation with model data that includes the terminal data set, and to receive the graph generated by the graph engine that spans the terminal points in the terminal data.

25. The system of claim 24, wherein the physical representation comprises a semiconductor chip layout, and the terminal data includes terminal points representative of physical locations within a plane of the semiconductor chip layout.

26. The system of claim 24, wherein the physical representation comprises an infrastructure layout, and the terminal data includes terminal points representative of physical locations within the infrastructure layout.

27. A computer-implemented system for graphical tree generation between terminal points, comprising:
means for storing a terminal data set; and
means for adding one or more vertices to strengthen one or more violated subtour inequalities (S) and obtain a graph spanning terminal points in the terminal data set.

28. A non-transitory computer-readable storage medium having control logic for causing at least one processor to generate a graph between terminal points, comprising:
first control logic configured to enable retrieval of a terminal data set; and
second control logic configured to enable adding one or more vertices to strengthen one or more violated subtour inequalities (S) and obtain a graph spanning terminal points in the retrieved terminal data set.
